(19) United States
(12) Patent Application Publication
(10) Pub. No.: US 2026/0150724 A1
(43) Pub. Date: May 28, 2026

(54) INTERPOSER, SEMICONDUCTOR PACKAGE INCLUDING THE INTERPOSER, AND METHOD OF MANUFACTURING THE SEMICONDUCTOR PACKAGE

(71) Applicant: Samsung Electronics Co., Ltd., Suwon-si (KR)

(72) Inventors: Dongkuk Lee, Suwon-si (KR); Seungduk Baek, Suwon-si (KR)

(21) Appl. No.: 19/276,608

(22) Filed: Jul. 22, 2025

(30) Foreign Application Priority Data
Nov. 28, 2024 (KR) 10-2024-0173948

(51) Int. Cl. H01L 23/538; H01L 23/58; H10B 80/00

(52) U.S. Cl. CPC H10W 70/611; H10W 42/00; H10W 70/635; H10W 90/401; H10B 80/00

(57) ABSTRACT

Examples of interposers for improving signal integrity and power integrity and reducing the size of a semiconductor package, and a semiconductor package including the interposer are provided. In one aspect, an interposer includes an interposer lower plate and an interposer upper plate and coupled to the interposer lower plate, wherein the interposer lower plate includes a first body layer, a first capacitor below the first body layer, a first interconnect layer below the first capacitor, and a first pad on an upper surface of the first body layer, the interposer upper plate includes a second body layer, a second capacitor above the second body layer, a second interconnect layer above the second capacitor, and a second pad on a lower surface of the second body layer, and the interposer lower plate is coupled to the interposer upper plate with the first pad being electrically connected to the second pad.

### CROSS-REFERENCE TO RELATED APPLICATION

This application is based on and claims priority under 35 U.S.C. §119 to Korean Patent Application No. 10-2024-0173948, filed on Nov. 28, 2024, in the Korean Intellectual Property Office, the disclosure of which is incorporated by reference herein in its entirety.

### BACKGROUND

With rapid developments in electronic industries and the user demand, electronic devices have had continually reduced size and weight. With electronic devices having reduced size and weight, a semiconductor package used in the electronic devices have also had reduced size and weight and been required to have high performance and large capacity as well as excellent reliability. For realization of the reduced size and weight, high performance, large capacity and excellent reliability, semiconductor chips including a through-silicon via (TSV) structure and a semiconductor package in which the semiconductor chips are stacked, have been continually researched and developed. In addition, an interposer, which connects semiconductor devices arranged at a top portion in the semiconductor package to each other or to a package substrate, has been mounted on the package substrate and used as a medium substrate.

### SUMMARY

The present disclosure provides an interposer for improving signal integrity (SI)/power integrity (PI) characteristics and reducing the size of a semiconductor package and a semiconductor package including the interposer.

Also, objectives of the present disclosure are not limited to those mentioned above, and other objectives will be clearly understood by one of ordinary skill in the art from the descriptions below.

According to an aspect of the present disclosure, an interposer includes an interposer lower plate and an interposer upper plate arranged above the interposer lower plate and coupled to the interposer lower plate, wherein the interposer lower plate includes a first body layer, a first capacitor below the first body layer, a first interconnect layer below the first capacitor, and a first pad on an upper surface of the first body layer, the interposer upper plate includes a second body layer, a second capacitor above the second body layer, a second interconnect layer above the second capacitor, and a second pad on a lower surface of the second body layer, and through coupling of the interposer lower plate with the interposer upper plate, the first pad is electrically connected to the second pad.

According to another aspect of the present disclosure, an interposer includes an interposer lower plate and an interposer upper plate arranged above the interposer lower plate and coupled to the interposer lower plate, wherein the interposer lower plate includes a first body layer, a first capacitor on the first body layer, a first interconnect layer on the first capacitor, a first pad on the first body layer or the first interconnect layer, and a first through electrode passing through the first body layer and connecting the first interconnect layer with the first pad, the interposer upper plate includes a second body layer, a second capacitor on the second body layer, a second interconnect layer on the second capacitor, a second pad on the second body layer or the second interconnect layer, and a second through electrode passing through the second body layer and connecting the second interconnect layer with the second pad, and through coupling of the interposer lower plate with the interposer upper plate, the first pad is electrically connected to the second pad.

According to another aspect of the present disclosure, a semiconductor package includes a package substrate, an interposer mounted on the package substrate and including an interposer lower plate and an interposer upper plate coupled to the interposer lower plate, and at least one semiconductor device mounted on the interposer, wherein the interposer lower plate includes a first body layer, a first capacitor below the first body layer, a first interconnect layer below the first capacitor, and a first pad on an upper surface of the first body layer, the interposer upper plate includes a second body layer, a second capacitor above the second body layer, a second interconnect layer above the second capacitor, and a second pad on a lower surface of the second body layer, and through coupling of the interposer lower plate with the interposer upper plate, the first pad is electrically connected to the second pad.

According to another aspect of the present disclosure, a method of manufacturing a semiconductor package includes: preparing an interposer substrate, mounting semiconductor devices on the interposer substrate, sealing the semiconductor devices on the interposer substrate through a sealing member, manufacturing an intermediate semiconductor package including an interposer and at least one semiconductor device, by separating the interposer substrate and the semiconductor devices, and mounting the intermediate semiconductor package on a package substrate, wherein the interposer includes an interposer lower plate including a first body layer, a first capacitor below the first body layer, a first interconnect layer below the first capacitor, a first pad on an upper surface of the first body layer, and a first through electrode passing through the first body layer and connecting the first interconnect layer with the first pad, and an interposer upper plate arranged above the interposer lower plate, coupled to the interposer lower plate, and including a second body layer, a second capacitor above the second body layer, a second interconnect layer above the second capacitor, a second pad on a lower surface of the second body layer, and a second through electrode passing through the second body layer and connecting the second interconnect layer with the second pad.

According to another aspect of the present disclosure, a method of manufacturing a semiconductor package includes preparing an interposer substrate comprising a plurality of interposer arranged along a first direction; mounting semiconductor devices on the interposer substrate along a second direction perpendicular to the first direction, the semiconductor devices being arranged along the first direction; sealing, using a sealant, the semiconductor devices on the interposer substrate to form a stacked structure; separating the stacked structure into a plurality of intermediate semiconductor packages, each of the plurality of intermediate semiconductor packages comprising a respective interposer of the plurality of interposer and at least one semiconductor device of the semiconductor devices; and mounting an intermediate semiconductor package of the plurality of intermediate semiconductor packages on a package substrate, wherein each of the plurality of interposers includes: a respective interposer lower plate comprising a first body layer, a first capacitor below the first body layer, a first interconnect layer below the first capacitor, a first pad on an upper surface of the first body layer, and a first through electrode extending through the first body layer, the first through electrode connecting the first interconnect layer with the first pad; and a respective interposer upper plate above the respective interposer lower plate and coupled to the respective interposer lower plate, the respective interposer upper plate comprising a second body layer, a second capacitor above the second body layer, a second interconnect layer above the second capacitor, a second pad on a lower surface of the second body layer, and a second through electrode extending through the second body layer, the second through electrode connecting the second interconnect layer with the second pad.

Preparing the interposer substrate may include manufacturing an interposer lower plate substrate; manufacturing an interposer upper plate substrate; and coupling the interposer upper plate substrate to the interposer lower plate substrate.

Manufacturing the interposer lower plate substrate may include: forming the first through electrode and the first capacitor in an initial first body layer; forming the first interconnect layer above the first through electrode and the first capacitor; and forming the first pad on a back side of the initial first body layer, wherein manufacturing the interposer upper plate substrate may include:
forming the second through electrode and the second capacitor in an initial second body layer;
forming the second interconnect layer above the second through electrode and the second capacitor; and forming the second pad on a back side of the initial second body layer, and wherein coupling the interposer upper plate substrate to the interposer lower plate substrate may include electrically connecting the first pad to the second pad.

Coupling the interposer upper plate substrate to the interposer lower plate substrate may include coupling the interposer upper plate substrate to the interposer lower plate substrate through hybrid copper bonding (HCB) or a connection terminal.

Preparing the interposer substrate may include forming one or more redistribution layers below the first interconnect layer and/or above the second interconnect layer.

### BRIEF DESCRIPTION OF THE DRAWINGS

Implementations will be more clearly understood from the following detailed description taken in conjunction with the accompanying drawings in which:

FIGS. 1A and 1B are a cross-sectional view and an enlarged view of an interposer according to an implementation;

FIGS. 2A and 2B are a cross-sectional view and an enlarged view of an interposer according to an implementation;

FIGS. 3A and 3B are cross-sectional views of interposers according to implementations;

FIGS. 4A to 4C are cross-sectional views of interposers according to implementations;

FIG. 5 is a cross-sectional view of a semiconductor package according to an implementation;

FIGS. 6A to 6C are more detailed cross-sectional views of a structure of a second semiconductor device in the semiconductor package of FIG. 5;

FIGS. 7A and 7B are cross-sectional views of semiconductor packages according to implementations;

FIGS. 8A to 8F are cross-sectional views for describing a method of manufacturing an interposer substrate, according to an implementation;

FIGS. 9A and 9B are cross-sectional views for describing a method of manufacturing an interposer substrate, according to an implementation;

FIG. 10 is a cross-sectional view for describing a method of manufacturing an interposer substrate, according to an implementation; and

FIGS. 11A to 11E are schematic cross-sectional views for describing a method of manufacturing a semiconductor package, according to an implementation.

### DETAILED DESCRIPTION

Hereinafter, implementations are described in detail with reference to the accompanying drawings. For the same elements on the drawings, the same reference numerals are used, and the descriptions are not repeated.

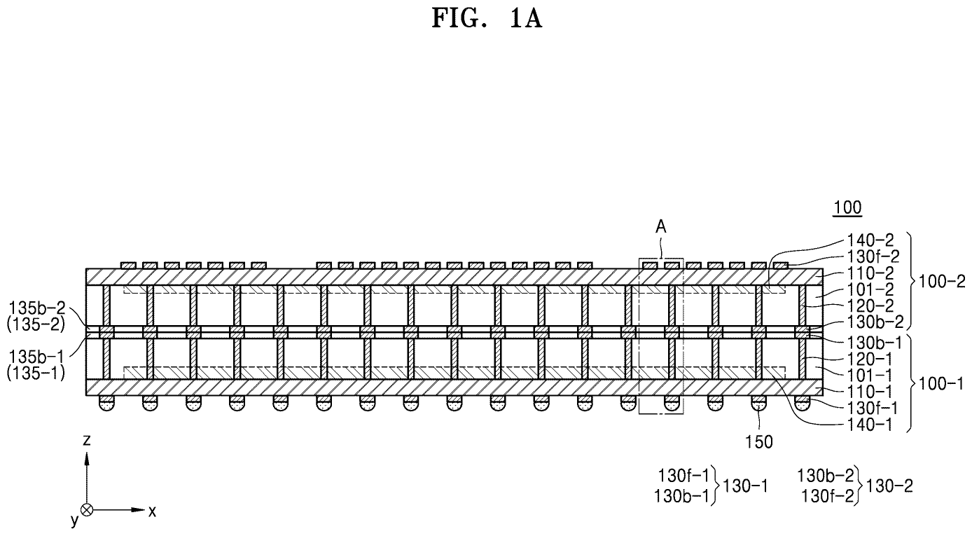

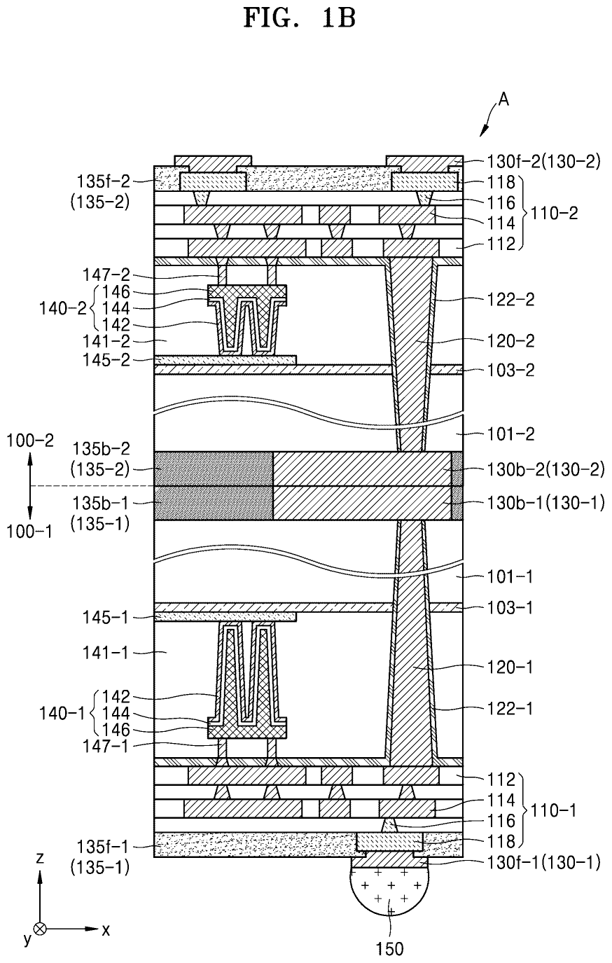

FIGS. 1A and 1B are a cross-sectional view and an enlarged view of an interposer 100 according to an implementation, wherein FIG. 1B is the enlarged view of region A of FIG. 1A.

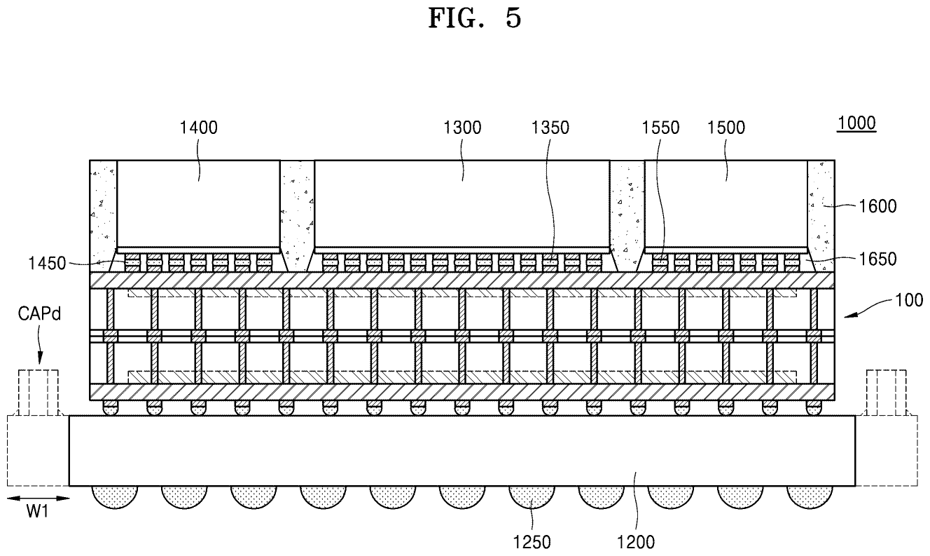

Referring to FIGS. 1A and 1B, the interposer 100 according to an implementation may mediate signal transmission between semiconductor devices 1300, 1400, and 1500 (see FIG. 5) mounted above the interposer 100. Also, the interposer 100 may mediate signal and power transmission, etc. between the semiconductor devices 1300, 1400, and 1500 and a package substrate 1200 (see FIG. 5). For example, the interposer 100 may be mounted on the package substrate 1200 and may connect the semiconductor devices 1300, 1400, and 1500 to the package substrate 1200.

The interposer 100 may include an interposer lower plate 100-1 and an interposer upper plate 100-2. Each of the interposer lower plate 100-1 and the interposer upper plate 100-2 may include silicon (Si). Accordingly, the interposer 100 may include a Si-interposer. The interposer lower plate 100-1 and the interposer upper plate 100-2 may be coupled to each other through hybrid copper bonding (HCB). Here, the HCB may denote bonding combining pad-to-pad bonding with insulator-to-insulator bonding. Because pads normally include copper (Cu), pad-to-pad bonding may be referred to as Cu-to-Cu bonding. The HCB are described in more detail below with respect to the coupling between a first back-side pad 130b-1 of the interposer lower plate 100-1 and a second back-side pad 130b-2 of the interposer upper plate 100-2.

The interposer lower plate 100-1 may include a first body layer 101-1, a first interconnect layer 110-1, a first through electrode 120-1, a first pad 130-1, a first capacitor 140-1, and a first external connection terminal 150. In the interposer lower plate 100-1, the first interconnect layer 110-1 may correspond to a front side. For example, a lower surface of the first interconnect layer 110-1 may correspond to the front side, and an upper surface of the first body layer 101-1 may correspond to a back side. The first body layer 101-1 may include, for example, Si.

The first interconnect layer 110-1 may be arranged below the first body layer 101-1. The upper end of the first interconnect layer 110-1 may be connected to the first through electrode 120-1, and the lower end of the first interconnect layer 110-1 may be connected to a first front-side pad 130f-1. Also, the first interconnect layer 110-1 may be connected to the first capacitor 140-1.

As illustrated in FIG. 1B, the first interconnect layer 110-1 may include an interlayer insulating layer 112, interconnect lines 114, a via 116, and an aluminum (Al) pad 118. Due to a multi-layered structure of the interconnect lines 114, the interlayer insulating layer 112 may have a multi-layered structure. All layers of the interlayer insulating layer 112 may include the same material, or at least one layer of the interlayer insulating layer 112 may include a different material. The interconnect lines 114 may be arranged in the interlayer insulating layer 112 as a multi-layered structure. The interconnect lines 114 of different layers may be connected to each other through the via 116. The interconnect lines 114 and the via 116 may include, for example, Cu. However, the materials of the interconnect lines 114 and the via 116 are not limited to Cu. The Al pad 118 may be arranged at a lower end of the first interconnect layer 110-1 and may be connected to the interconnect lines 114 through the via 116. The Al pad 118 may be covered by a first front-side protective layer 135f-1. According to some implementations, the Al pad 118 may be included in the interconnect lines 114.

The first through electrode 120-1 may pass through the first body layer 101-1 to extend in a vertical direction, that is, a z direction. The first body layer 101-1 may include Si, and thus, the first through electrode 120-1 may correspond to a through silicon via (TSV). As illustrated in FIG. 1B, the first through electrode 120-1 may have a structure in which an upper portion of the first through electrode 120-1 is narrow and a lower portion of the first through electrode 120-1 is wide. This may be because the first through electrode 120-1 is formed by forming a trench on the lower side of the first body layer 101-1. However, according to some implementations, the upper portion and the lower portion of the first through electrode 120-1 may have similar widths.

The lower end of the first through electrode 120-1 may be connected to the interconnect lines 114 of the first interconnect layer 110-1 and, through the interconnect lines 114, the first through electrode 120-1 may be connected to the first front-side pad 130f-1 on the lower surface of the first interconnect layer 110-1 and to the first external connection terminal 150. Also, the upper end of the first through electrode 120-1 may be connected to the first back-side pad 130b-1 on the first body layer 101-1.

The first through electrode 120-1 may have a cylindrical shape and may include a barrier layer on its exterior surface and a buried conductive layer inside. The barrier layer may include at least one material selected from among Ti, TiN, Ta, TaN, Ru, Co, Mn, WN, Ni, and NiB. The buried conductive layer may include at least one material selected from among Cu, Cu alloys, such as CuSn, CuMg, CuNi, CuZn, CuPd, CuAu, CuRe, CuW, W, W alloys, Ni, Ru, and Co.

Also, a first electrode insulating layer 122-1 may be arranged between the first through electrode 120-1 and the first body layer 101-1 or between the first through electrode 120-1 and the first interconnect layer 110-1. The first electrode insulating layer 122-1 may include, for example, an oxide layer, a nitride layer, a carbide layer, a polymer, or a combination thereof. As illustrated in FIG. 1B, the first electrode insulating layer 122-1 may cover side surfaces of the first through electrode 120-1 and may extend on an upper surface of the first interconnect layer 110-1.

The first pad 130-1 may include the first front-side pad 130f-1 and the first back-side pad 130b-1. The first front-side pad 130f-1 may be arranged on the lower surface of the first interconnect layer 110-1. Also, the first front-side pad 130f-1 may be connected to the interconnect lines 114 through the Al pad 118 and the via 116. The first back-side pad 130b-1 may be arranged on an upper surface of the first body layer 101-1 and may be connected to the first through electrode 120-1. The first pad 130-1 may include, for example, at least one of Al, Cu, Ni, W, Pt, and Au. In the interposer 100 according to an implementation, the first pad 130-1 may include Cu. However, the material of the first pad 130-1 is not limited to Cu.

A first protective layer 135-1 may be arranged on a lower surface and an upper surface of the interposer lower plate 100-1. The first protective layer 135-1 may include a first back-side protective layer 135b-1 and a first front-side protective layer 135f-1. The first back-side protective layer 135b-1 may be arranged on the upper surface of the first body layer 101-1. The first back-side pad 130b-1 may be arranged to have a structure to pass through the first back-side protective layer 135b-1. For example, the first back-side pad 130b-1 may pass through the first back-side protective layer 135b-1 and may be connected to the first through electrode 120-1. The first front-side protective layer 135f-1 may be arranged on the lower surface of the first interconnect layer 110-1. The first front-side pad 130f-1 may be arranged to have a structure to pass through a portion of the first front-side protective layer 135f-1. For example, the first front-side pad 130f-1 may pass through a portion of the first front-side protective layer 135f-1 and may be connected to the Al pad 118 in the first front-side protective layer 135f-1. The first protective layer 135-1 may include, for example, an oxide layer, a nitride layer, a carbide layer, a polymer, or a combination thereof. However, the material of the first protective layer 135-1 is not limited thereto. The first protective layer 135-1 may have a single-layered or a multi-layered structure.

The first capacitor 140-1 may be arranged in the first body layer 101-1. The first capacitor 140-1 may include, for example, an integrated stack capacitor (ISC). The ISC may have a large amount of capacitance, for example, several to dozens of nF, based on its structure. The first capacitor 140-1 may include a lower electrode 142, an upper electrode 146, and a dielectric layer 144. The lower electrode 142 and the upper electrode 146 may include polysilicon. Thus, based on the structure and material, the lower electrode 142 may be referred to as a storage poly, and the upper electrode 146 may be referred to as a plate poly. However, according to some implementations, the lower electrode 142 and the upper electrode 146 may include metal materials.

The first capacitor 140-1 may be arranged in a first body insulating layer 141-1 on the first body layer 101-1. A first separation insulating layer 103-1 may be arranged between the first body layer 101-1 and the first body insulating layer 141-1. However, according to some implementations, the first separation insulating layer 103-1 may be omitted. A first plate electrode 145-1 may be arranged on the first separation insulating layer 103-1. The first plate electrode 145-1 may be connected to the lower electrode 142. A first cap through electrode 147-1 may pass through a portion of the first body insulating layer 141-1 that corresponds to the upper electrode 146 and may be connected to the upper electrode 146. Although not shown, a second cap through electrode may pass through the first body layer 101-1 and the first body insulating layer 141-1 and may be connected to the first plate electrode 145-1. In addition, in FIG. 1B, the first capacitor 140-1 is illustrated to have a structure in which 2 V-shapes are connected. However, in reality, the first capacitor 140-1 may have a structure in which a number of V-shapes are connected.

The first external connection terminal 150 may be arranged on the first front-side pad 130f-1 on the lower surface of the interposer lower plate 100-1. The first external connection terminal 150 may be connected to the first through electrode 120-1 through the first front-side pad 130f-1 and the first interconnect layer 110-1. The first external connection terminal 150 may include a solder. The solder may include In, Bi, Sb, Cu, Ag, Zn, and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. The solder may be referred to as a bump, a solder bump, etc.

According to some implementations, the first external connection terminal 150 may include a pillar, and the solder may be arranged on the pillar. The pillar may include, for example, Ni, Cu, Pd, Pt, Au, or a combination thereof. According to some implementations, the pillar may function as a pad and may include Cu. In this case, the pillar may be referred to as a bump pad, a Cu-pad, a Cu-pillar, etc. Also, when the pillar functions as a pad, the first front-side pad 130f-1 may be omitted.

The interposer upper plate 100-2 may be arranged on the interposer lower plate 100-1. The interposer upper plate 100-2 may include a second body layer 101-2, a second interconnect layer 110-2, a second through electrode 120-2, a second pad 130-2, and a second capacitor 140-2. In the interposer upper plate 100-2, the second interconnect layer 110-2 may correspond to a front side. That is, an upper surface of the second interconnect layer 110-2 may correspond to the front side, and a lower surface of the second body layer 101-2 may correspond to a back side.

The components of the interposer upper plate 100-2 may be substantially the same as the components of the interposer lower plate 100-1. However, the interposer upper plate 100-2 may be arranged in the opposite direction to the interposer lower plate 100-1. In detail, the front side of the interposer lower plate 100-1 may be toward a lower direction and the back side of the interposer lower plate 100-1 may be toward an upper direction, while the front side of the interposer upper plate 100-2 may be toward the upper direction and the back side of the interposer upper plate 100-2 may be toward the lower direction. As described above, in the interposer 100 according to an implementation, the interposer upper plate 100-2 and the interposer lower plate 100-1 may be arranged in the opposite direction to each other, and thus, the components of the interposer upper plate 100-2 may be at symmetrical locations with the components of the interposer lower plate 100-1 in the z direction. For example, the first pad 130-1 and the second pad 130-2 may be arranged at symmetrical locations. Thus, with respect to the arrangement locations and functions, the first back-side pad 130b-1 may correspond to the second back-side pad 130b-2, and the first front-side pad 130f-1 may correspond to the second front-side pad 130f-2.

However, the first external connection terminal 150 may be arranged on the first front-side pad 130f-1, while external connection terminals 1350, 1450, and 1550 (see FIG. 5) of the semiconductor devices 1300, 1450, and 1500 (see FIG. 5) mounted on the interposer 100, may be arranged on the second front-side pad 130f-2. Thus, the first front-side pad 130f-1 may have a different size and a different pitch from the second front-side pad 130f-2. For example, the size and the pitch of the second front-side pad 130f-2 may be less than the size and the pitch of the first front-side pad 130f-1. Also, due to the difference between the first front-side pad 130f-1 and the second front-side pad 130f-2, the connection structure and the number of layers of the interconnect lines 114 may be different between the first interconnect layer 110-1 and the second interconnect layer 110-2.

In addition, the interposer lower plate 100-1 connected to the first external connection terminal 150 may be formed to have a greater thickness than the interposer upper plate 100-2. Thus, as illustrated in FIG. 1B, the first capacitor 140-1 may have a greater size and a greater capacitance than the second capacitor 140-2. However, the size and the capacitance of the first capacitor 140-1 and the second capacitor 140-2 are not limited thereto. For example, according to some implementations, the first capacitor 140-1 may have substantially the same size and capacitance as the second capacitor 140-2.

Other aspects about the second body layer 101-2, the second interconnect layer 110-2, the second through electrode 120-2, the second pad 130-2, and the second capacitor 140-2 may be the same as the first body layer 101-1, the first interconnect layer 110-1, the first through electrode 120-1, the first pad 130-1, and the first capacitor 140-1 of the interposer lower plate 100-1 described above.

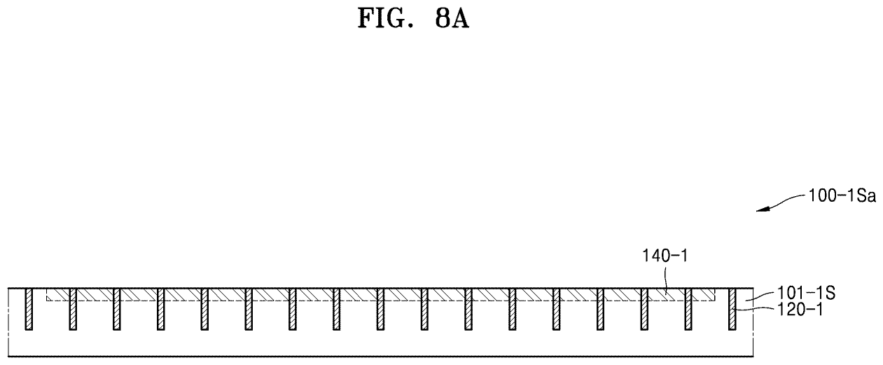

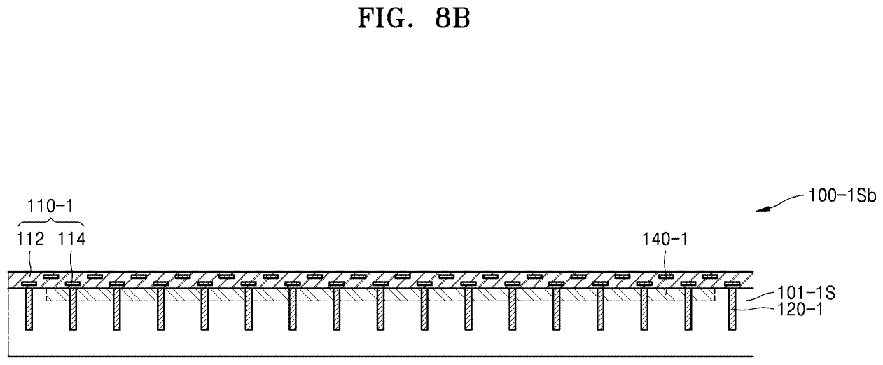

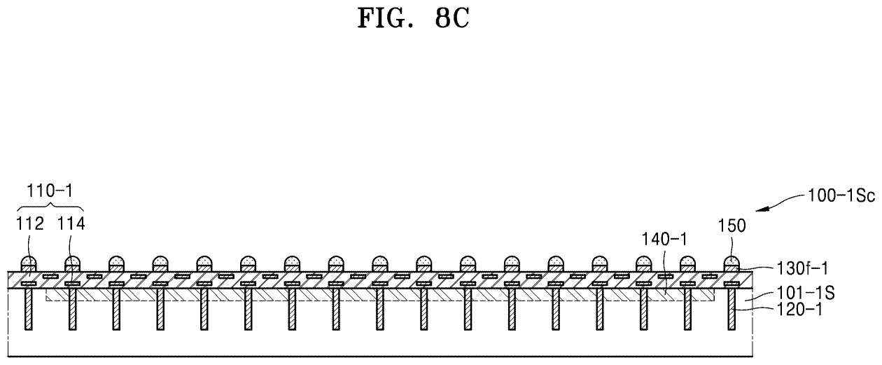

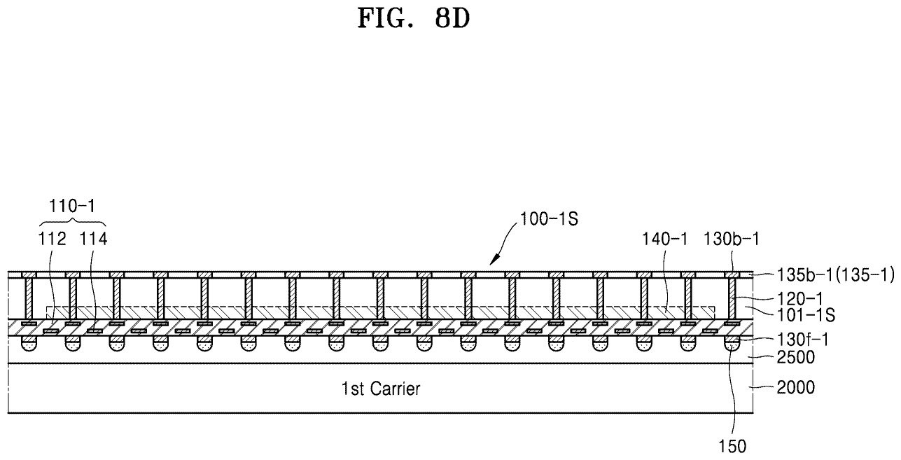

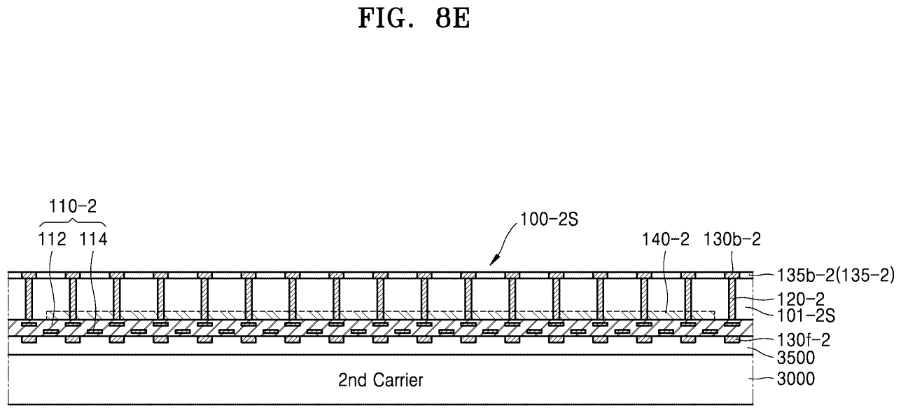

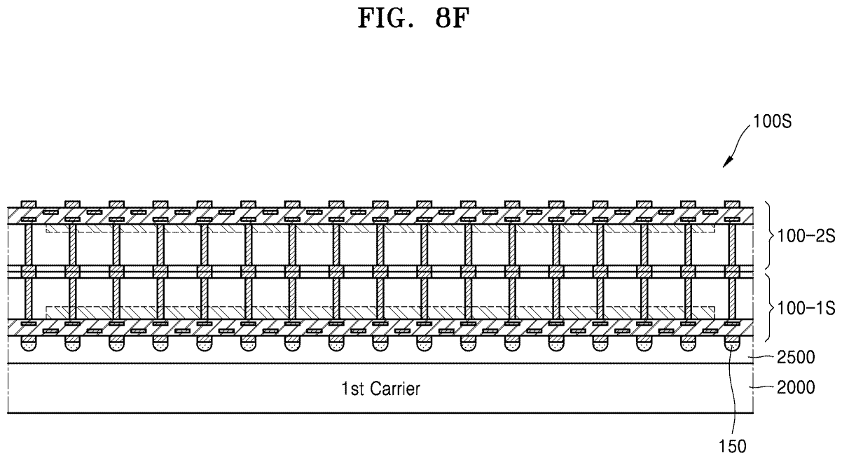

In the interposer 100 according to an implementation, the interposer lower plate 100-1 and the interposer upper plate 100-2 may be coupled to each other through the HCB as described above. For example, the first back-side pad 130b-1 of the interposer lower plate 100-1 may be coupled to the corresponding second back-side pad 130b-2 of the interposer upper plate 100-2, and the first back-side protective layer 135b-1 of the interposer lower plate 100-1 may be coupled to the second back-side protective layer 135b-2 of the interposer upper plate 100-2. Aspects about the HCB are to be described in more detail with a method of manufacturing an interposer substrate with reference to FIGS. 8A to 8F.

The interposer 100 according to an implementation may include a two and a half-dimensional (2.5D) interposer. For reference, the interposer 100 may include a 2.5D interposer and a two and a third-dimensional (2.3D) interposer. Also, according to some implementations, the structure of the interposer 100 may be further specified by including a Si-bridge. Thus, structures except for a 2.5D interposer will be referred to as two and an xth-dimensional (2.xD) interposers. The 2.5D interposer may usually denote a Si-interposer and may include a TSV inside. The 2.3D interposer may denote an organic or inorganic interposer. When the 2.3D interposer includes a through electrode, the through electrode may be referred to as a through dielectric via (TDV), a through glass via (TGV), etc., according to the material of a body layer. According to some implementations, the 2.3D interposer may be referred to as a panel level package (PLP) interposer, a redistribution layer (RDL) interposer, etc.

The interposer 100 according to an implementation may have a structure in which the interposer lower plate 100-1 and the interposer upper plate 100-2 are coupled to each other through HCB. Also, the interposer lower plate 100-1 and the interposer upper plate 100-2 may include the first and second capacitors 140-1 and 140-2 having an ISC structure. Thus, when a system in package (SiP) is formed by including the interposer 100 according to an implementation, the interposer 100 may provide sufficient capacitors, and thus, the signal integrity (SI)/power integrity (PI) characteristics may be improved without additionally arranging capacitors. Also, because an additional external capacitor needs not be arranged, the size of the SiP may be reduced by as much as the size and soldering area of an additional capacitor. Furthermore, the first capacitor 140-1 may be arranged to have a large size on the lower surface of the interposer 100, for example, on the front side of the interposer lower plate 100-1, to be adjacent to the package substrate 1200 (see FIG. 5), and thus, the total capacity of the capacitors of the SiP may be improved. Additionally, the PI characteristics may be improved as capacitors are arranged to be adjacent to power/ground, and because, based on a second external connection terminal 1250 (see FIG. 5) of the package substrate 1200 connected to the power/ground, the first capacitor 140-1 may be arranged on the front side of the interposer lower plate 100-1, the PI characteristics may be further improved.

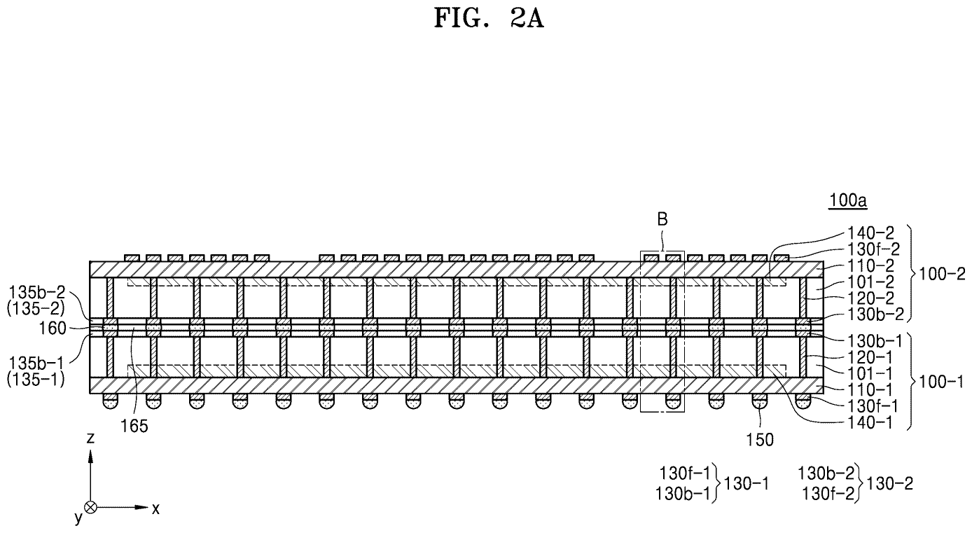

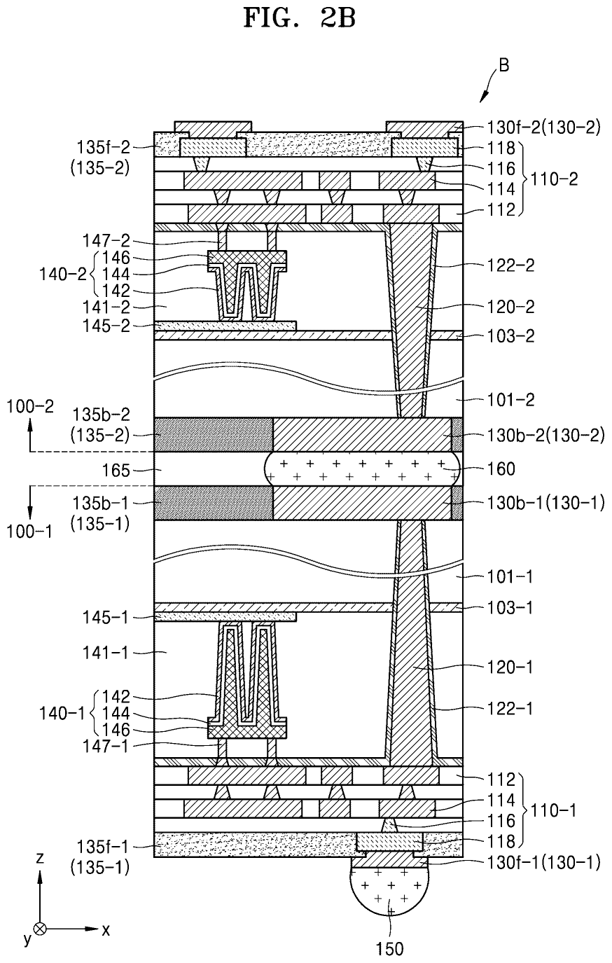

FIGS. 2A and 2B are a cross-sectional view and an enlarged view of an interposer 100a according to an implementation, wherein FIG. 2B is the enlarged view of region B of FIG. 2A. Aspects that are described above with reference to FIGS. 1A and 1B are briefly described or are not repeatedly described.

Referring to FIGS. 2A and 2B, the interposer 100a according to an implementation may differ from the interposer 100 of FIG. 1A in that the interposer lower plate 100-1 and the interposer upper plate 100-2 are coupled to each other through an inter-plate connection terminal 160. In detail, the interposer 100a according to an implementation may include the interposer lower plate 100-1, the interposer upper plate 100-2, and the inter-plate connection terminal 160. The interposer lower plate 100-1 and the interposer upper plate 100-2 may be the same as described with reference to the interposer lower plate 100-1 and the interposer upper plate 100-2 of the interposer 100 of FIG. 1A. Thus, the interposer lower plate 100-1 and the interposer upper plate 100-2 may each include Si. Also, the interposer 100a according to an implementation may correspond to a Si-interposer.

In the interposer 100a according to an implementation, the interposer lower plate 100-1 and the interposer upper plate 100-2 may be coupled to each other through the inter-plate connection terminal 160. The inter-plate connection terminal 160 may be arranged between the first back-side pad 130b-1 of the interposer lower plate 100-1 and the second back-side pad 130b-2 of the interposer upper plate 100-2. The inter-plate connection terminal 160 may include, for example, a solder. The solder may be the same as described with reference to the first external connection terminal 150 of the interposer 100 of FIG. 1A. According to some implementations, the inter-plate connection terminal 160 may further include a pillar, and the solder may be arranged on the pillar. The pillar may also be the same as described with reference to the first external connection terminal 150 of the interposer 100 of FIG. 1A.

Because the interposer lower plate 100-1 and the interposer upper plate 100-2 may be coupled to each other through the inter-plate connection terminal 160, an adhesive layer 165 may be arranged between the interposer lower plate 100-1 and the interposer upper plate 100-2. For example, the adhesive layer 165 may fill a space between the interposer lower plate 100-1 and the interposer upper plate 100-2 and may cover side surfaces of the inter-plate connection terminals 160. The adhesive layer 165 may include, for example, a non-conductive film (NCF). Generally, the NCF may be used as an adhesive layer when a semiconductor chip is bonded through thermal compression bonding (TCB) in a semiconductor chip stacking process. However, in the interposer 100a according to an implementation, the material of the adhesive layer 165 is not limited to the NCF. Also, according to some implementations, an underfill or a molding member such as an epoxy molding compound (EMC), rather than the adhesive layer 165, may be filled in the space between the interposer lower plate 100-1 and the interposer upper plate 100-2.

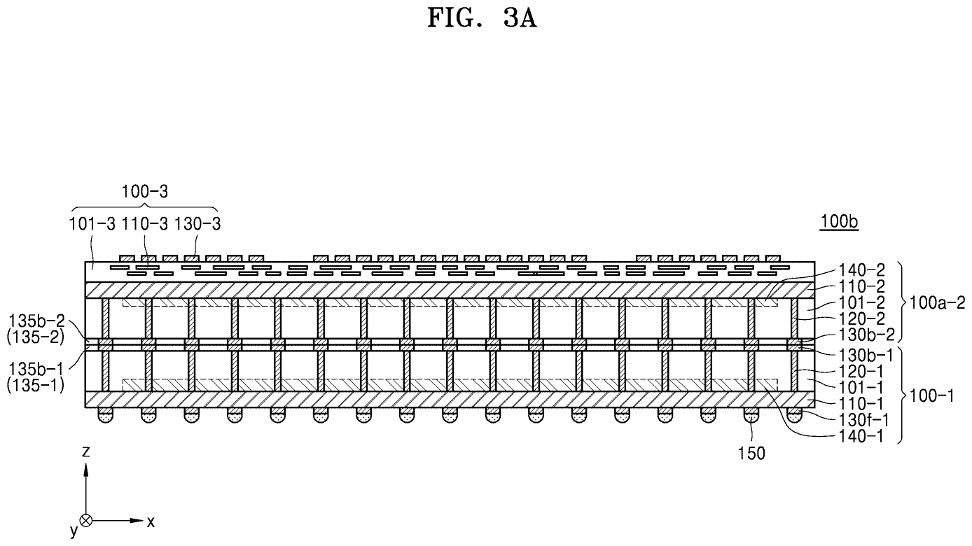

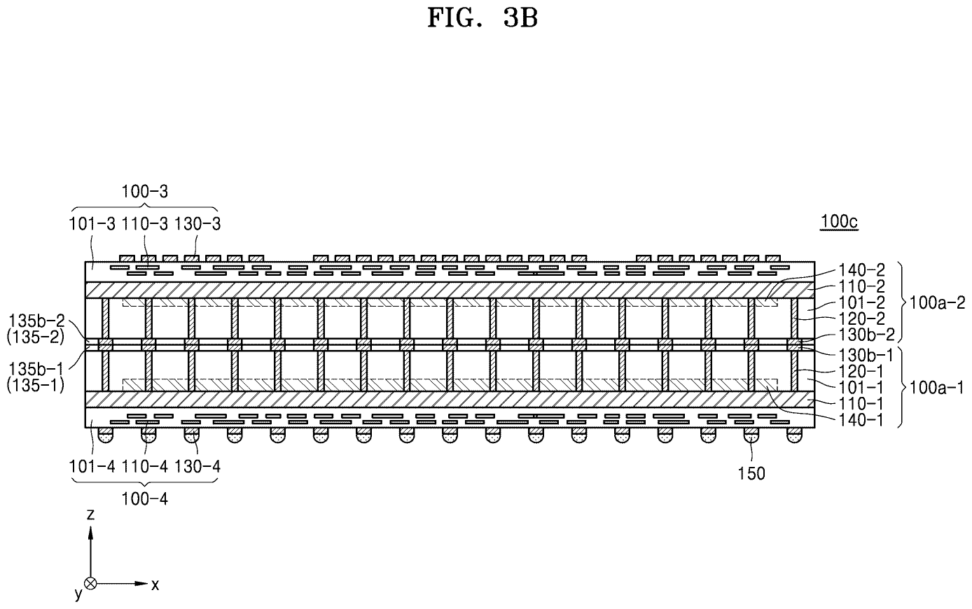

FIGS. 3A and 3B are cross-sectional views of interposers 100b and 100c according to implementations. Aspects described above with reference to FIGS. 1A to 2B are briefly described or are not repeatedly described.

Referring to FIG. 3A, the interposer 100b according to an implementation may differ from the interposer 100 of FIG. 1A in that the interposer 100b may further include a first redistribution layer 100-3. In detail, the interposer 100b according to an implementation may include the interposer lower plate 100-1, an interposer upper plate 100a-2, and the first redistribution layer 100-3. The interposer lower plate 100-1 and the interposer upper plate 100a-2 may be the same as described with reference to the interposer lower plate 100-1 and the interposer upper plate 100-2 of the interposer 100 of FIG. 1A. However, as illustrated in FIG. 3A, the second front-side pad 130f-2 may be omitted in the interposer upper plate 100a-2. However, according to some implementations, the second front-side pad 130f-2 may be maintained in the interposer upper plate 100a-2.

The interposer lower plate 100-1 and the interposer upper plate 100a-2 may each include Si and may be coupled to each other through HCB. Thus, the interposer 100b according to an implementation may correspond to a Si-interposer. However, in the interposer 100b according to an implementation, the interposer lower plate 100-1 and the interposer upper plate 100a-2 are not limited to coupling through HCB and may be coupled to each other through the inter-plate connection terminal 160.

The first redistribution layer 100-3 may be arranged on the interposer upper plate 100a-2. However, the first redistribution layer 100-3 is not limited thereto and may be arranged on the interposer lower plate 100-1. When the first redistribution layer 100-3 is arranged on the interposer lower plate 100-1, the first redistribution layer 100-3 may be arranged on the interposer lower plate 100-1 as the same structure as a second redistribution layer 100-4 of the interposer 100c of FIG. 3B.

The first redistribution layer 100-3 may include a first redistribution body layer 101-3, a first redistribution line 110-3, and a first redistribution pad 130-3. The first redistribution body layer 101-3 may include, for example, photo imageable dielectric (PID) or photo imageable polyimide (PIP) resins, and may further include an inorganic pillar. However, the material of the first redistribution body layer 101-3 is not limited to the materials described above. For example, the first redistribution body layer 101-3 may include polyimide isoindro quirazorindione (PIQ), polyimide (PI), polybenzoxazole (PBO), etc.

The first redistribution line 110-3 may be arranged in the first redistribution body layer 101-3. When the first redistribution line 110-3 includes a plurality of layers, the plurality of first redistribution lines 110-3 on different layers may be connected to each other through a via. The first redistribution line 110-3 may be connected to the interconnect lines 114 of the second interconnect layer 110-2 of the interposer upper plate 100a-2. For reference, the first redistribution line 110-3 may be connected to the Al pad 118 of the second interconnect layer 110-2 through a via. When the second front-side pad 130f-2 is arranged on the second interconnect layer 110-2, the first redistribution line 110-3 may be connected to the second front-side pad 130f-2 through a via.

The first redistribution pad 130-3 may be arranged on an upper surface of the first redistribution layer 100-3. The external connection terminals 1350, 1450, and 1550 of the semiconductor devices 1300, 1400, and 1500 mounted on the interposer 100b may be arranged on the first redistribution pad 130-3.

Referring to FIG. 3B, the interposer 100c according to an implementation may differ from the interposer 100b of FIG. 3A in that the interposer 100c may further include the second redistribution layer 100-4. In detail, the interposer 100c according to an implementation may include an interposer lower plate 100a-1, the interposer upper plate 100a-2, the first redistribution layer 100-3, and the second redistribution layer 100-4. The interposer lower plate 100a-1, the interposer upper plate 100a-2, and the first redistribution layer 100-3 may be the same as the interposer lower plate 100-1, the interposer upper plate 100a-2, and the first redistribution layer 100-3 of the interposer 100b of FIG. 3A. However, as illustrated in FIG. 3B, the first front-side pad 130f-1 may be omitted in the interposer lower plate 100a-1. However, according to some implementations, the first front-side pad 130f-1 may be maintained in the interposer lower plate 100a-1.

The interposer lower plate 100a-1 and the interposer upper plate 100a-2 may each include Si and may be coupled to each other through HCB. Thus, the interposer 100c according to an implementation may correspond to a Si-interposer. In the interposer 100c according to an implementation, the interposer lower plate 100a-1 and the interposer upper plate 100a-2 are not limited to coupling through HCB and may be coupled to each other through the inter-plate connection terminal 160.

The second redistribution layer 100-4 may be arranged on the interposer lower plate 100a-1. The second redistribution layer 100-4 may include a second redistribution body layer 101-4, a second redistribution line 110-4, and a second redistribution pad 130-4. The second redistribution layer 100-4 may differ from the first redistribution layer 100-3 in terms of the arrangement position. Also, the second redistribution pad 130-4 may differ from the first redistribution pad 130-3 in terms of the size, pitch, etc., and thus, the connection relationship and/or the number of layers of the second redistribution line 110-4 may be different from the connection relationship and/or the number of layers of the first redistribution line 110-3. In addition, the general structure, material, etc. of the second redistribution layer 100-4 may be substantially the same as the general structure, material, etc. of the first redistribution layer 100-3.

The second redistribution line 110-4 may be connected to the interconnect lines 114 of the first interconnect layer 110-1 of the interposer lower plate 100a-1. For reference, the second redistribution line 110-4 may be connected to the Al pad 118 of the first interconnect layer 110-1 through a via. When the first front-side pad 130f-1 is arranged on the first interconnect layer 110-1, the second redistribution line 110-4 may be connected to the first front-side pad 130f-1 through a via.

The second redistribution pad 130-4 may be arranged on a lower surface of the second redistribution layer 100-4. As illustrated in FIG. 3B, the first external connection terminals 150 may be arranged on the second redistribution pad 130-4.

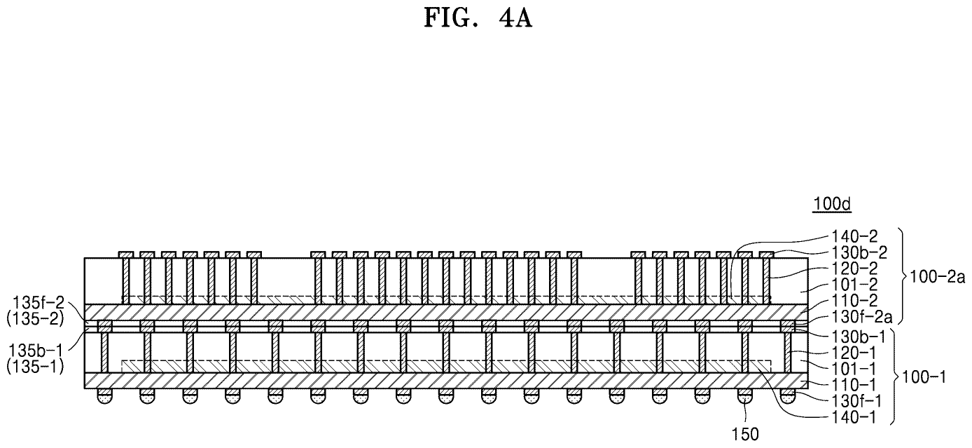

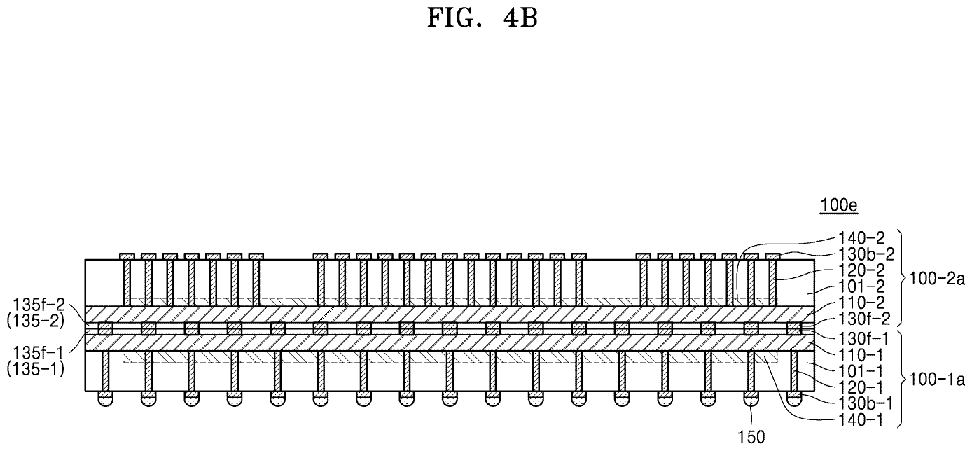

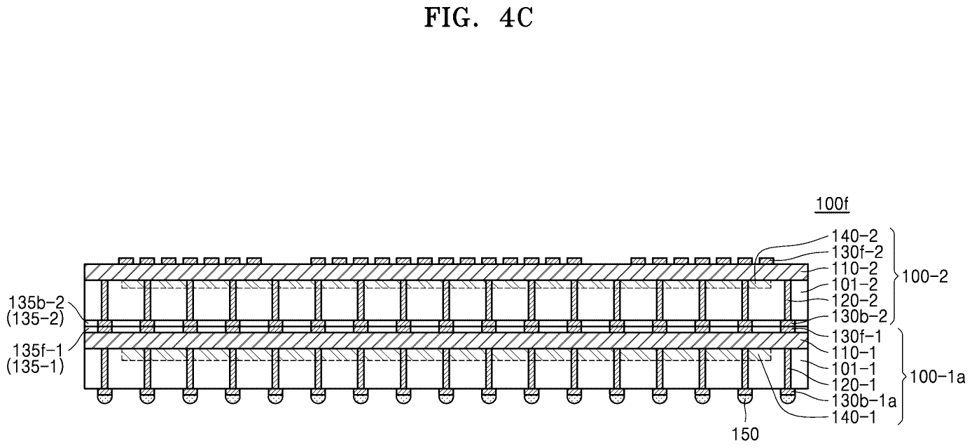

FIGS. 4A to 4C are cross-sectional views of interposers 100d, 100e, and 100f according to implementations. Aspects described above with reference to FIGS. 1A to 3B are briefly described or are not repeatedly described.

Referring to FIG. 4A, the interposer 100d according to an implementation may differ from the interposer 100 of FIG. 1A in terms of a coupling direction of the interposer lower plate 100-1 and an interposer upper plate 100-2a. In detail, the interposer 100d according to an implementation may include the interposer lower plate 100-1 and the interposer upper plate 100-2a. Except for the coupling direction of the interposer lower plate 100-1 and the interposer upper plate 100-2a, the interposer lower plate 100-1 and the interposer upper plate 100-2a may be the same as described with reference to the interposer lower plate 100-1 and the interposer upper plate 100-2 of the interposer 100 of FIG. 1A.

The interposer lower plate 100-1 and the interposer upper plate 100-2a may each include Si and may be coupled to each other through HCB. Thus, the interposer 100d according to an implementation may correspond to a Si-interposer. In the interposer 100d according to an implementation, the interposer lower plate 100-1 and the interposer upper plate 100-2a are not limited to coupling through HCB and may be coupled to each other through the inter-plate connection terminal 160.

In the interposer 100d according to an implementation, the interposer lower plate 100-1 and the interposer upper plate 100-2a may be coupled to each other through a back-side and a front-side. In detail, in the interposer 100d according to an implementation, the back side of the interposer lower plate 100-1 may be coupled to the front side of the interposer upper plate 100-2a. Accordingly, the first back-side pad 130b-1 of the interposer lower plate 100-1 may be coupled to the corresponding second front-side pad 130f-2 of the interposer upper plate 100-2a. Also, the first protective layer 135-1, for example, the first back-side protective layer 135b-1, of the interposer lower plate 100-1, may be coupled to the second protective layer 135-2, for example, the second front-side protective layer 135f-2, of the interposer upper plate 100-2a. In the present disclosure, the front side may be referred to the side that includes the first interconnect layer or the second interconnect layer. The back side may refer to the side that includes the first body layer or the second body layer. An upper surface may refer to a topmost or a top layer of a layer or a structure, or a surface that faces upward (e.g., along positive Z direction). A lower surface may refer to a bottommost or a bottom layer of a layer or a structure, or a surface that faces downward (e.g., along negative Z direction).

In the interposer 100d according to an implementation, the external connection terminals 1350, 1450, and 1550 of the semiconductor devices 1300, 1400, and 1500 may be arranged on the second back-side pad 130b-2 on the back side of the interposer upper plate 100-2a. Also, the second back-side pad 130b-2 may be directly connected to the second through electrode 120-2. Thus, the second back-side pad 130b-2 and the second through electrode 120-2 may be arranged to have a smaller pitch compared to the second back-side pad 130b-2 and the second through electrode 120-2 of the interposer upper plate 100-2 of the interposer 100 of FIG. 1A.

Referring to FIG. 4B, the interposer 100e according to an implementation may differ from the interposer 100 of FIG. 1A in terms of a coupling direction of an interposer lower plate 100-1a and the interposer upper plate 100-2a. In detail, the interposer 100e according to an implementation may include the interposer lower plate 100-1a and the interposer upper plate 100-2a. Except for the coupling direction, the interposer lower plate 100-1a and the interposer upper plate 100-2a may be the same as described with respect to the interposer lower plate 100-1 and the interposer upper plate 100-2 of the interposer 100 of FIG. 1A.

The interposer lower plate 100-1a and the interposer upper plate 100-2a may each include Si and may be coupled to each other through HCB. Thus, the interposer 100e according to an implementation may correspond to a Si-interposer. In the interposer 100e according to an implementation, the interposer lower plate 100-1a and the interposer upper plate 100-2a are not limited to coupling through HCB and may be coupled to each other through the inter-plate connection terminal 160.

In the interposer 100e according to an implementation, the interposer lower plate 100-1a and the interposer upper plate 100-2a may be coupled to each other through a front-side and a front-side. In detail, in the interposer 100e according to an implementation, the front side of the interposer lower plate 100-1a may be coupled to the front side of the interposer upper plate 100-2a. Thus, the first front-side pad 130f-1 of the interposer lower plate 100-1a may be coupled to the corresponding second front-side pad 130f-2 of the interposer upper plate 100-2a. Also, the first protective layer 135-1, for example, the first front-side protective layer 135f-1, of the interposer lower plate 100-1a, may be coupled to the second protective layer 135-2, for example, the second front-side protective layer 135f-2, of the interposer upper plate 100-2a.

In the interposer 100e according to an implementation, the external connection terminals 1350, 1450, and 1550 of the semiconductor devices 1300, 1400, and 1500 may be arranged on the second back-side pad 130b-2 on the back side of the interposer upper plate 100-2a. Also, the second back-side pad 130b-2 may be directly connected to the second through electrode 120-2. Thus, the second back-side pad 130b-2 and the second through electrode 120-2 may be arranged to have a smaller pitch compared to the second back-side pad 130b-2 and the second through electrode 120-2 of the interposer upper plate 100-2 of the interposer 100 of FIG. 1A.

Referring to FIG. 4C, the interposer 100f according to an implementation may differ from the interposer 100 of FIG. 1A in terms of a coupling direction of the interposer lower plate 100-1a and the interposer upper plate 100-2. In detail, the interposer 100f according to an implementation may include the interposer lower plate 100-1a and the interposer upper plate 100-2. Except for the coupling direction, the interposer lower plate 100-1a and the interposer upper plate 100-2 may be the same as described with respect to the interposer lower plate 100-1 and the interposer upper plate 100-2 of the interposer 100 of FIG. 1A.

The interposer lower plate 100-1a and the interposer upper plate 100-2 may each include Si and may be coupled to each other through HCB. Thus, the interposer 100f according to an implementation may correspond to a Si-interposer. In the interposer 100f according to an implementation, the interposer lower plate 100-1a and the interposer upper plate 100-2 are not limited to coupling through HCB and may be coupled to each other through the inter-plate connection terminal 160.

In the interposer 100f according to an implementation, the interposer lower plate 100-1a and the interposer upper plate 100-2 may be coupled to each other through a front-side and a back-side. In detail, in the interposer 100f according to an implementation, the front side of the interposer lower plate 100-1a may be coupled to the back side of the interposer upper plate 100-2. Thus, the first front-side pad 130f-1 of the interposer lower plate 100-1a may be coupled to the corresponding second back-side pad 130b-2 of the interposer upper plate 100-2. Also, the first protective layer 135-1, for example, the first front-side protective layer 135f-1, of the interposer lower plate 100-1a, may be coupled to the second protective layer 135-2, for example, the second back-side protective layer 135b-2, of the interposer upper plate 100-2.

FIG. 5 is a cross-sectional view of a semiconductor package 1000 according to an implementation. FIG. 5 is described with reference to FIGS. 1A and 1B together, and aspects described above with reference to FIGS. 1A to 4C are briefly described or are not repeatedly described.

Referring to FIG. 5, the semiconductor package 1000 according to an implementation may include the interposer 100, the package substrate 1200, the semiconductor devices 1300, 1400, and 1500, and an external sealing member 1600.

For example, the interposer 100 may correspond to the interposer 100 of FIG. 1A. Thus, the interposer 100 may include the interposer lower plate 100-1 and the interposer upper plate 100-2, wherein the interposer lower plate 100-1 and the interposer upper plate 100-2 may be coupled to each other through HCB. In the semiconductor package 1000 according to an implementation, the interposer 100 is not limited to the interposer 100 of FIG. 1A. For example, instead of the interposer 100 of FIG. 1A, one of the interposers 100a to 100f with reference to FIGS. 2A, 3A, 3B, and 4A to 4C, respectively, may be included in the semiconductor package 1000.

The package substrate 1200 may be a support substrate, and the interposer 100, the semiconductor devices 1300, 1400, and 1500, etc. may be stacked on the package substrate 1200. In the package substrate 1200, an interconnect line of at least one layer may be provided. When the interconnect line includes a plurality of layers, the interconnect lines on different layers may be connected to each other through a via. The package substrate 1200 may be formed based on, for example, a ceramic substrate, a printed circuit board (PCB), a glass substrate, an interposer substrate, etc. The second external connection terminal 1250 may be arranged on a lower surface of the package substrate 1200. The semiconductor package 1000 according to an implementation may be stacked on an external system substrate, a main board, etc. through the second external connection terminal 1250.

The interposer 100 may be mounted on the package substrate 1200 through the first external connection terminal 150. The semiconductor devices 1300, 1400, and 1500 may be mounted on the package substrate 1200 with the interposer 100 as a medium. The interposer 100 may connect the semiconductor devices 1300, 1400, and 1500 to each other. Also, the interposer 100 may connect the semiconductor devices 1300, 1400, and 1500 to the package substrate 1200. In the semiconductor package 1000 according to an implementation, the interposer 100 may be used for converting electrical signals or transmitting electrical signals between the semiconductor devices 1300, 1400, and 1500. Thus, active devices may not be provided in the interposer 100. However, according to some implementations, the interposer 100 may include devices for controlling signal transmission. Although not shown, underfill may be filled between the interposer 100 and the package substrate 1200 and between the first external connection terminals 150. According to some implementations, the underfill may be replaced by an adhesive layer or an adhesive film.

The semiconductor devices 1300, 1400, and 1500 may include a first semiconductor device 1300, a second semiconductor device 1400, and a third semiconductor device 1500.

The first semiconductor device 1300 may be stacked on a central portion of the interposer 100 through a third external connection terminal 1350. The first semiconductor device 1300 may have a chip or package structure. In the semiconductor package 1000 according to an implementation, the first semiconductor device 1300 may have a chip structure. For example, the first semiconductor device 1300 may include a logic chip. A plurality of logic devices may be included in the first semiconductor device 1300. The logic devices may include, for example, an AND, a NAND, an OR, a NOR, an exclusive OR (XOR), an exclusive NOR (XNOR), an inverter (INV), an adder (ADD), a delay (DLY), filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, or a latch, a counter, or buffer devices. The logic devices may perform various signal processing, such as analog signal processing, analog-to-digital (A/D) conversion, controlling, etc. The first semiconductor device 1300 may be referred to as a central processing unit (CPU) chip, a micro-processor unit (MPU) chip, a graphics processing unit (GPU) chip, a neural processing unit (NPU) chip, a system on glass (SOG) chip, an application specific integrated circuit (ASIC) chip, an application processor (AP) chip, a control chip, or the like, based on its function.

In the semiconductor package 1000 according to an implementation, the first semiconductor device 1300 may have the chip structure, which may include a system on chip (SoC) structure or a chiplet structure. In an SoC structure, various systems may be integrated into a single chip. Thus, the first semiconductor device 1300 having the SoC structure may execute calculation, data storage, A/D signal conversion, etc. in a single chip. In a chiplet structure, a logic chip may be split into separate functional chips and the chips may be connected to each other. The first semiconductor device 1300 having the chiplet structure may overcome a performance limit of the single chip.

In the semiconductor package 1000 according to an implementation, the second semiconductor device 1400, which is adjacent to the left side of the first semiconductor device 1300, may be stacked on the left portion of the interposer 100 through a fourth external connection terminal 1450. Also, the third semiconductor device 1500, which is adjacent to the right side of the first semiconductor device 1300, may be stacked on the right portion of the interposer 100 through a fifth external connection terminal 1550. However, the locations at which the second semiconductor device 1400 and the third semiconductor device 1500 are arranged are not limited thereto. For example, the location of the second semiconductor device 1400 may be exchanged with the location of the third semiconductor device 1500.

In the semiconductor package 1000 according to an implementation, any one of the second semiconductor device 1400 and the third semiconductor device 1500 may be a memory device, and the other may be a logic device. Also, according to some implementations, both of the second semiconductor device 1400 and the third semiconductor device 1500 may be memory devices.

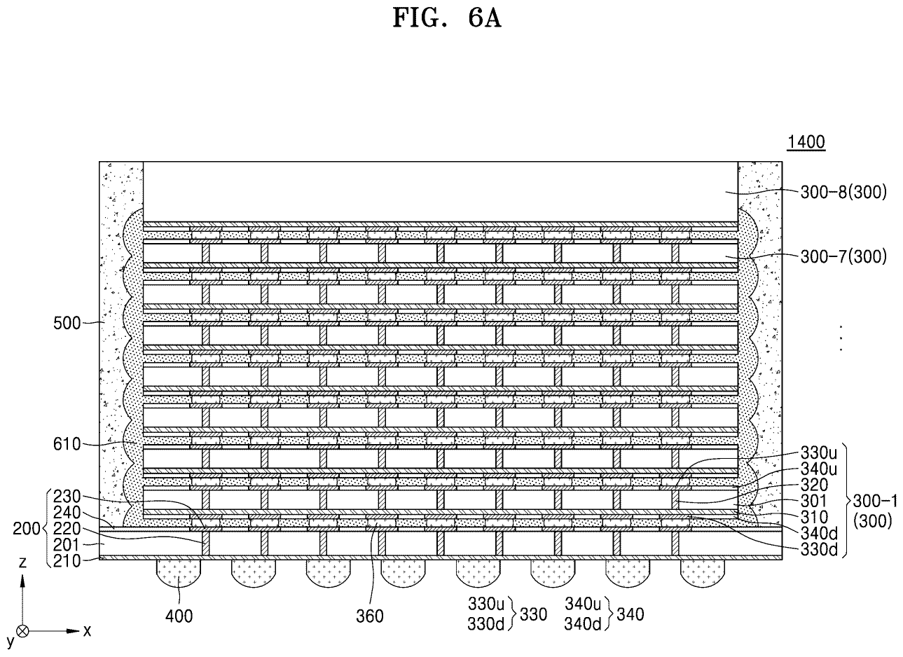

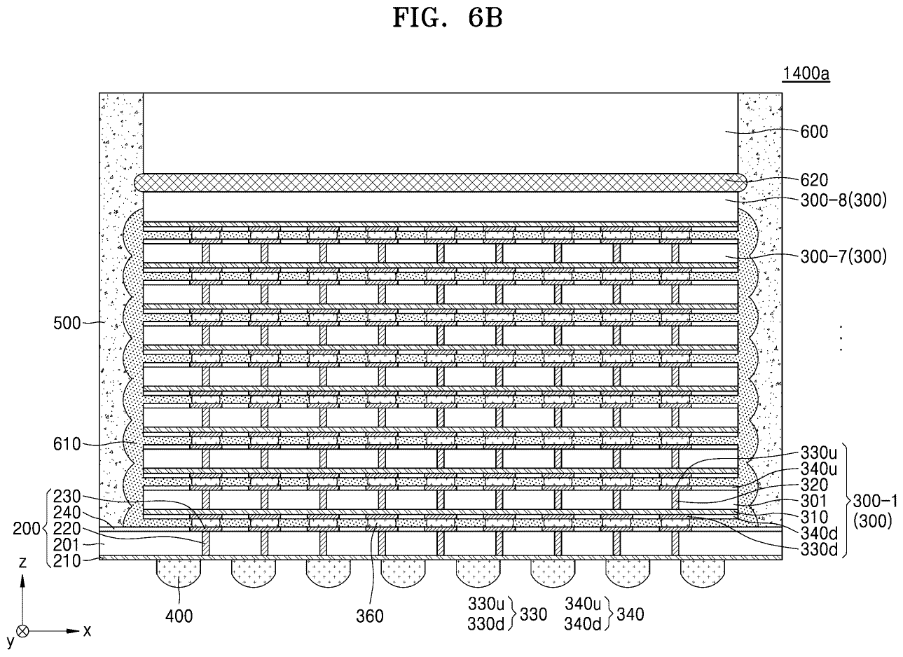

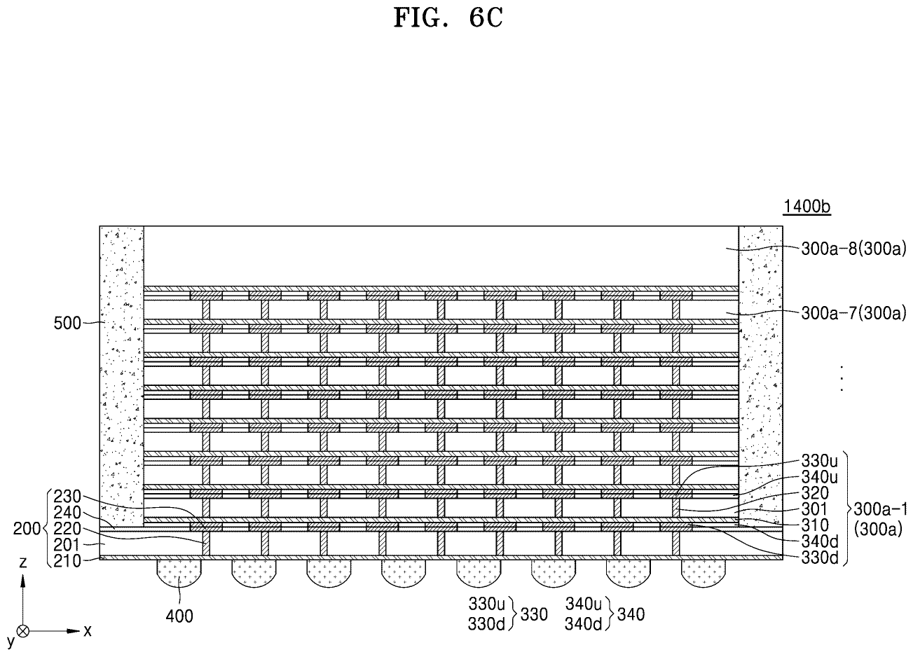

For example, when the second semiconductor device 1400 is a memory device and the third semiconductor device 1500 is a logic device, the second semiconductor device 1400 may include a memory package, for example, a high bandwidth memory (HBM) package. However, the second semiconductor device 1400 is not limited to the HBM package. For example, the second semiconductor device 1400 may have a single chip structure or may have a general package structure that is different from the HBM package. Aspects about the second semiconductor device 1400 having the HBM package structure are to be described in more detail with reference to FIGS. 6A to 6C.

The third semiconductor device 1500, which is the logic device, may include a logic chip. For example, the third semiconductor device 1500 may include a modem chip supporting communication of the first semiconductor device 1300. However, the type of the third semiconductor device 1500 is not limited to the modem chip. For example, the third semiconductor device 1500 may include other types of logic chips for supporting an operation of the first semiconductor device 1300 or for performing various signal processing operations together with or independently from the first semiconductor device 1300.

When both of the second semiconductor device 1400 and the third semiconductor device 1500 are memory devices, both of the second semiconductor device 1400 and the third semiconductor device 1500 may include an HBM package. In the semiconductor package 1000 of FIG. 5, the two semiconductor devices, which are memory devices, may be arranged to be adjacent to the first semiconductor device 1300. However, the number of semiconductor devices, which are memory devices, is not limited to two. For example, three or more semiconductor devices, which are memory devices, may be arranged to be adjacent to the first semiconductor device 1300, which is a logic device. Also, each of the three or more semiconductor devices may include an HBM package.

The external sealing member 1600 may cover and seal the semiconductor devices 1300, 1400, and 1500 on the interposer 100. As illustrated in FIG. 5, the external sealing member 1600 may not cover upper surfaces of the semiconductor devices 1300, 1400, and 1500. However, according to some implementations, the external sealing member 1600 may cover the upper surface of at least one of the semiconductor devices 1300, 1400, and 1500.

The semiconductor package 1000 according to an implementation may have an SiP structure including the interposer 100 of FIG. 1A. Thus, as described above, the semiconductor package 1000 according to an implementation may have improved SI/PI characteristics without additionally arranged capacitors and may reduce the size of an SiP. To describe, in more detail, the SiP having the reduced size, FIG. 5 illustrates additional capacitors CAPd indicated by dashed lines at both sides of the package substrate 1200. Like this, when the additional capacitor CAPd is arranged on the package substrate 1200, the area of the package substrate 1200 may be increased by as much as the size and the soldering area of the additional capacitor CAPd. For example, when the additional capacitors CAPd are arranged, the size of the package substrate 1200 may be increased by an area corresponding to 2*W1 in FIG. 5, and thus, the total size of the SiP may be increased. However, in the case of the semiconductor package 1000 according to an implementation, there may be no need to arrange the additional capacitor CAPd, which may contribute to reducing the size of the SiP.

For reference, the structure of the semiconductor package 1000 according to an implementation is referred to as a 2.5D package structure. The 2.5D package structure may be a relative concept with respect to a three-dimensional (3D) package structure, in which all semiconductor chips are stacked together and there is no interposer. Both of the 2.5D package structure and the 3D package structure may be included in the SiP structure.

FIGS. 6A to 6C are more detailed cross-sectional views of a structure of the second semiconductor device 1400 in the semiconductor package 1000 of FIG. 5. FIGS. 6A to 6C are described with reference to FIG. 5, and aspects described above with reference to FIGS. 1A to 5 are briefly described or are not repeatedly described.

Referring to FIG. 6A, in the semiconductor package 1000 according to an implementation, the second semiconductor device 1400 may have an HBM package structure. In detail, the second semiconductor device 1400 may include a base chip 200, memory chips 300, a first connection terminal 400, and an inner sealing member 500. The base chip 200 may have a greater size than the memory chips 300 arranged thereabove, as illustrated in FIG. 6A. However, the size of the base chip 200 is not limited thereto. For example, according to some implementations, the base chip 200 may have substantially the same size as the memory chips 300.

The base chip 200 may include a chip body 201, an active layer 210, a through electrode 220, a connection pad 230, and a protective layer 240. The chip body 201 may include a semiconductor element, for example, Si or Ge. Also, the chip body 201 may include a compound semiconductor, such as SiC, GaAs, InAs, or InP. The chip body 201 may have a silicon on insulator (SOI) structure. For example, the chip body 201 may include a buried oxide (BOX) layer. The chip body 201 may include a conductive area, for example, a well doped with impurities or a structure such as source/drain areas doped with impurities. The chip body 201 may have various device isolation structures, such as a shall trench isolation (STI) structure.

The active layer 210 may include an integrated circuit layer and an interconnect layer on the integrated circuit layer. In general, the integrated circuit layer may include various types of devices. For example, the integrated circuit layer may include various active devices and/or passive devices, such as a transistor, logic devices, memory devices, system large scale integration (LSI), a complementary metal oxide semiconductor (CMOS) imaging sensor (CIS), a micro-electro-mechanical system (MEMS). The transistor may include, for example, a bipolar junction transistor (BJT) or a field effect transistor (FET), such as a planar FET, a FinFET, etc. The logic devices may be the same as described above with respect to the first semiconductor device 1300 of the semiconductor package 1000 of FIG. 5. The memory devices may include a volatile memory device, such as dynamic random-access memory (DRAM) or static random-access memory (SRAM), or a non-volatile memory device, such as flash memory, phase-change random-access memory (PRAM), magneto-resistive random-access memory (MRAM), ferroelectric random-access memory (FeRAM), or resistive random-access memory (RRAM).

The interconnect layer may connect at least two devices to each other, connect the devices with a conductive area of the chip body 201, or connect the devices to the first connection terminal 400. Also, the interconnect layer may connect the through electrode 220 with the first connection terminal 400. The interconnect layer may include, for example, interconnect lines, a contact, or a via. In the second semiconductor device 1400 according to an implementation, the active layer 210 may be arranged below the chip body 201 and the through electrode 220. However, according to some implementations, the active layer 210 may be arranged above the chip body 201 and the through electrode 220.

In the second semiconductor device 1400 according to an implementation, the base chip 200 may include a plurality of logic devices in the integrated circuit layer of the active layer 210. The base chip 200 may be arranged below the memory chips 300, may combine signals from the memory chips 300 and transmit the combined signals to the outside, and may transmit signals and power from the outside to the memory chips 300. Thus, the base chip 200 may be referred to as a buffer chip or an interface chip.

According to some implementations, the base chip 200 may include a controller for controlling signal transmission between the memory chips 300 and an external device. When the base chip 200 includes a controller, the base chip 200 may be referred to as a logic chip or a control chip. Also, according to some implementations, the base chip 200 may include a power management integrated circuit (PMIC) for managing power or clocks. Furthermore, according to some implementations, the base chip 200 may include logic devices for operations. For reference, when the base chip 200 is referred to as a buffer chip, etc., the memory chips 300 may be referred to as a core chip.

In the second semiconductor device 1400 according to an implementation, the base chip 200 is not limited to a buffer chip or a logic chip. For example, the base chip 200 may include a plurality of memory devices in the integrated circuit layer of the active layer 210. Thus, the base chip 200 may include a memory chip.

The through electrode 220 may pass through the chip body 201 to extend from an upper surface to a lower surface of the chip body 201. According to some implementations, the through electrode 220 may extend into the active layer 210. In the second semiconductor device 1400 according to an implementation, the chip body 201 may include Si, and thus, the through electrode 220 may be referred to as a TSV. Other structures or materials of the through electrode 220 may be the same as described with respect to the first through electrode 120-1 of the interposer lower plate 100-1 of FIG. 1A.

The connection pad 230 may be arranged on the upper surface of the chip body 201 and may be connected to the through electrode 220. The protective layer 240 may be arranged on the upper surface of the chip body 201. Other materials or structures of the connection pad 230 and the protective layer 240 may be the same as described with respect to the first pad 130-1 and the first protective layer 135 of the interposer lower plate 100-1 of FIG. 1A. Although not shown, a protective layer may be arranged also on a lower surface of the active layer 210.

The memory chips 300 may be stacked on the base chip 200. In the second semiconductor device 1400 according to an implementation, eight memory chips 300, for example, first to eighth memory chips 300-1 to 300-8, may be stacked on the base chip 200. However, the number of memory chips 300 stacked on the base chip 200 is not limited to eight. For example, two to seven memory chips 300 or nine or more memory chips 300 may be stacked on the base chip 200.

For reference, in the second semiconductor device 1400, the memory chips 300 may include 4n (n is a natural number) memory chips. Accordingly, the second semiconductor device 1400 may include memory chips 300 in multiples of four, for example, four, eight, or twelve memory chips 300. Also, each four memory chips 300 may be tested and operated together by having the same stack-ID. For example, when the second semiconductor device 1400 includes eight memory chips 300, the first to fourth memory chips 300-1 to 300-4 may have a first stack-ID, and the fifth to eighth memory chips 300-5 to 300-8 may have a second stack-ID. However, the second semiconductor device 1400 is not limited to the memory chips 300 in multiples of four and the corresponding stack-ID. For example, the second semiconductor device 1400 may include memory chips 300 in multiples of two and the corresponding stack-ID or memory chips 300 in multiples of eight and the corresponding stack-ID.

The first to eighth memory chips 300-1 to 300-8 may have substantially the same horizontal size and inner structure. However, the eighth memory chip 300-8 arranged uppermost may not include a through electrode. Also, as illustrated in FIG. 6A, the eighth memory chip 300-8 may have a greater thickness than the other memory chips 300. According to some implementations, the thickness of the eighth memory chip 300-8 may be adjusted so that the total height of the second semiconductor device 1400 may be adjusted. Hereinafter, with respect to the detailed structure of the memory chip 300, the first memory chip 300-1 is described, for convenience.

The first memory chip 300-1 may include a chip body 301, an active layer 310, a through electrode 320, a connection pad 330, and a protective layer 340. Aspects about the chip body 301 may be the same as described with respect to the chip body 201 of the base chip 200.

The active layer 310 may include a plurality of memory devices. For example, the active layer 310 may include a volatile memory device, such as DRAM or SRAM, or nonvolatile memory devices, such as PRAM, MRAM, FeRAM, or RRAM. For example, in the second semiconductor device 1400, the first memory chip 300-1 may include DRAM devices in the active layer 310. Thus, the first memory chip 300-1 may be a DRAM chip. Also, because the second semiconductor device 1400 may be an HBM package, the first memory chip 300-1 may be a DRAM chip for HBM.

The through electrode 320 may pass through the chip body 301 or may pass through the chip body 301 to extend into the active layer 310. For example, the first memory chip 300-1 may be split into a cell area and a pad area, and when the through electrode 320 is formed only in the pad area, the through electrode 320 may pass through the chip body 301 and extend into the active layer 310. Other aspects about the through electrode 320 may be the same as described with respect to the through electrode 220 of the base chip 200.

The connection pad 330 may include a lower connection pad 330d arranged on a lower surface of the active layer 310 and an upper connection pad 330u arranged on an upper surface of the chip body 301. In a general semiconductor chip, a chip pad may be arranged on a lower surface of an active layer. Thus, the lower connection pad 330d may correspond to a chip pad of the first memory chip 300-1.

The lower connection pad 330d may be connected to interconnect lines of an interconnect layer of the active layer 310 on a lower surface of the chip body 301. Also, the lower connection pad 330d may be connected to the through electrode 320 through the interconnect lines of the interconnect layer. The upper connection pad 330u may be connected to the through electrode 320 on an upper surface of the chip body 301. Other aspects about the connection pad 330 may be the same as described with respect to the connection pad 230 of the base chip 200.

The protective layer 340 may include a lower protective layer 340d arranged on the lower surface of the active layer 310 and an upper protective layer 340u arranged on the upper surface of the chip body 301. Other aspects about the protective layer 340 may be the same as described with respect to the protective layer 240 of the base chip 200.

In the second semiconductor device 1400 according to an implementation, the memory chips 300 may be stacked on the base chip 200 or the memory chip 300 directly therebelow, through an inter-chip connection terminal 360. For example, the inter-chip connection terminal 360 may be arranged between the connection pad 230 of the base chip 200 and the lower connection pad 330d of the first memory chip 300-1. Also, the inter-chip connection terminal 360 may be arranged between the upper connection pad 330u of a lower memory chip 300 and the lower connection pad 330d of an upper memory chip 300 of the two adjacent lower and upper memory chips 300. The inter-chip connection terminal 360 may be the same as described above with respect to the inter-plate connection terminal 160 of the interposer 100a of FIG. 2A. For example, the inter-chip connection terminal 360 may include a solder or a pillar and a solder.

In the second semiconductor device 1400 according to an implementation, the memory chips 300 may be stacked through the inter-chip connection terminal 360, and thus, an adhesive layer 610 may be arranged between the base chip 200 and the first memory chip 300-1 and between two adjacent memory chips 300. For example, the adhesive layer 610 may be filled between the base chip 200 and the first memory chip 300-1 and between the two adjacent memory chips 300 and may cover side surfaces of the inter-chip connection terminals 360. Also, the adhesive layer 610 may protrude from side surfaces of the memory chips 300 and cover the side surfaces of the memory chips 300 as illustrated in FIG. 6A. According to some implementations, while the adhesive layer 610 may protrude from the side surfaces of the memory chips 300, the adhesive layer 610 may cover only a portion of the side surface of each of the memory chips 300. In this case, the adhesive layer 610 at an upper end and the adhesive layer 610 at a lower end may not be bonded to each other and may be apart from each other, at the side surface of each of the memory chips 300. The adhesive layer 610 may include, for example, an NCF. However, the material of the adhesive layer 610 is not limited to the NCF.

The first connection terminal 400 may be arranged on a lower surface of the base chip 200. The first connection terminal 400 may be connected to interconnect lines of an interconnect layer of the active layer 210. Also, the first connection terminal 400 may be connected to the through electrode 220 through the interconnect lines of the interconnect layer. Although not shown, a chip pad may be arranged on a lower surface of the base chip 200, and the first connection terminal 400 may be arranged on the chip pad.

The first connection terminal 400 may have a similar structure as the inter-chip connection terminals 360 described above. For example, the first connection terminal 400 may include a solder. According to some implementations, the first connection terminal 400 may include a pillar and a solder. Aspects about the pillar and the solder of the first connection terminal 400 may be the same as described with respect to the first external connection terminal 150 of the interposer 100 of FIG. 1A.

The inner sealing member 500 may surround side surfaces of the memory chips 300 on the base chip 200. As illustrated in FIG. 6A, the inner sealing member 500 may not cover an upper surface of the memory chip on the uppermost end, for example, the eighth memory chip 300-8. Thus, the upper surface of the eighth memory chip 300-8 may be exposed through the inner sealing member 500. However, according to some implementations, the inner sealing member 500 may cover the upper surface of the memory chip on the uppermost end, for example, the eighth memory chip 300-8. The inner sealing member 500 may include, for example, electromagnetic compatibility (EMC). However, the material of the inner sealing member 500 is not limited to the EMC.

Referring to FIG. 6B, in the semiconductor package 1000 according to an implementation, a second semiconductor device 1400a may have an HBM package structure, but may differ from the second semiconductor device 1400 of FIG. 6A in that the second semiconductor device 1400a may further include a top dummy chip 600. In detail, the second semiconductor device 1400a may include the base chip 200, the memory chips 300, the first connection terminal 400, the inner sealing member 500, and the top dummy chip 600. Aspects about the base chip 200, the memory chips 300, the first connection terminal 400, and the inner sealing member 500 may be the same as described with respect to the second semiconductor device 1400 of FIG. 6A. However, because the top dummy chip 600 may be added, the inner sealing member 500 may have a structure to cover up to a side surface of the top dummy chip 600.

In the second semiconductor device 1400a, the top dummy chip 600 may be stacked above the memory chips 300 through an adhesive layer 620. The top dummy chip 600 may be added according to the height standards of the second semiconductor device 1400a. For example, in the case of the HBM package, the height, area, etc. are defined in the joint electron device engineering council (JEDEC) standards, and because the second semiconductor device 1400a is an HBM package, the top dummy chip 600 having an appropriate height may be arranged on the memory chips 300, so that the second semiconductor device 1400a may have the height according to the JEDEC standards.

In the second semiconductor device 1400a, because the top dummy chip 600 may be added, the eighth memory chip 300-8 may have a thickness similar to a thickness of the other memory chips 300. However, the eighth memory chip 300-8 is not limited thereto. According to some implementations, even when the top dummy chip 600 is included, the eighth memory chip 300-8 may have a greater thickness than the other memory chips 300. However, when the total height of the second semiconductor device may be adjusted by adjusting the thickness of the eighth memory chip 300-8, the top dummy chip 600 may be omitted.

Referring to FIG. 6C, in the semiconductor package 1000 according to an implementation, while a second semiconductor device 1400b may have an HBM package structure, the second semiconductor device 1400b may differ from the second semiconductor device 1400 of FIG. 6A in that memory chips 300a may be stacked through HCB. In detail, the second semiconductor device 1400b may include the base chip 200, the memory chips 300a, the first connection terminal 400, and the inner sealing member 500. Aspects about the base chip 200, the first connection terminal 400, and the inner sealing member 500 may be the same as described with respect to the second semiconductor device 1400 of FIG. 6A. However, because the memory chips 300a may be stacked through HCB without the inter-chip connection terminal 360, there may be no adhesive layer filled between the memory chips 300a and the base chip 200 and between the adjacent memory chips 300a.

In the second semiconductor device 1400b, the memory chips 300a may be stacked on the base chip 200 or the memory chips 300a directly therebelow through HCB. Also, according to some implementations, a TCB method may be used for stacking the memory chips 300a through HCB. In more detail, as described above, the connection pad 230 and the protective layer 240 may be arranged on an upper surface of the base chip 200. Also, the connection pad 330 and the protective layer 340 may be arranged on a lower surface and an upper surface of each of the memory chips 300a. The connection pad 230 of the base chip 200 may be arranged to be buried in the protective layer 240 and may have an upper surface exposed through the protective layer 240. Also, the connection pad 330 of the memory chip 300a may be arranged to be buried in the protective layer 340 and may have an upper surface or a lower surface exposed through the protective layer 340. The protective layers 240 and 340 may include an insulating layer, such as SiO₂, SiN, SiCN, etc.

The connection pad 230 of the base chip 200 may be coupled to a lower connection pad 230d of a first memory chip 300a-1, and the protective layer 240 of the base chip 200 may be coupled to the lower protective layer 340d of the first memory chip 300a-1, and thus, HCB may be formed between the base chip 200 and the first memory chip 300a-1. Also, in the memory chips 300a, the upper connection pad 330u and the upper protective layer 340u on an upper surface of a lower memory chip 300a may be coupled to the lower connection pad 330d and the lower protective layer 340d on a lower surface of an upper memory chip 300a, between the two adjacent lower and upper memory chips 300a, and thus, HCB may be formed.

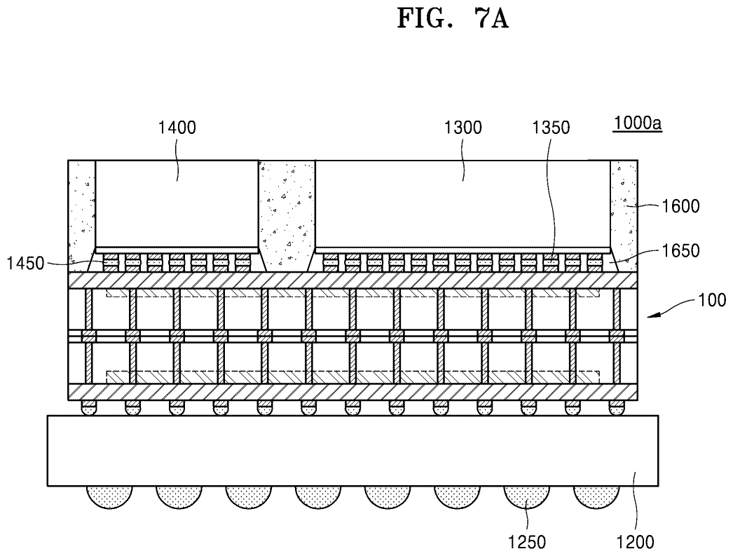

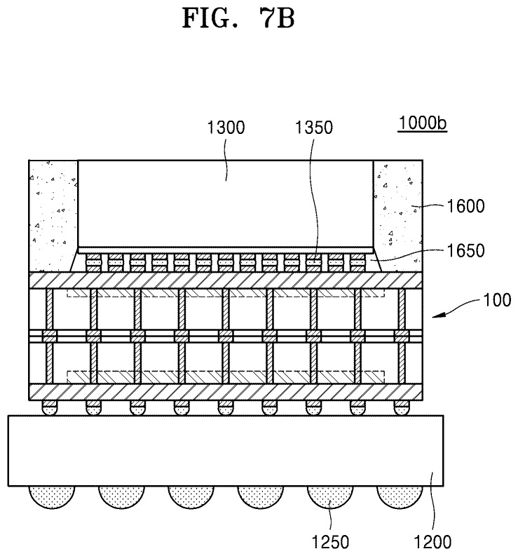

FIGS. 7A and 7B are cross-sectional views of semiconductor packages 1000a and 1000b according to implementations. FIGS. 7A and 7B are described with reference to FIG. 5, and aspects described above with reference to FIGS. 1A to 6C are briefly described or are not repeatedly described.

Referring to FIG. 7A, the semiconductor package 1000a according to an implementation may differ from the semiconductor package 1000 of FIG. 5 in that the semiconductor package 1000a may include only the first semiconductor device 1300 and the second semiconductor device 1400. In detail, the semiconductor package 1000a according to an implementation may include the interposer 100, the package substrate 1200, the first and second semiconductor devices 1300 and 1400, and the external sealing member 1600.

The interposer 100 may correspond to, for example, the interposer 100 of FIG. 1A. Thus, the interposer 100 may include the interposer lower plate 100-1 and the interposer upper plate 100-2, and the interposer lower plate 100-1 and the interposer upper plate 100-2 may be coupled to each other through HCB. In the semiconductor package 1000a according to an implementation, the interposer 100 is not limited to the interposer 100 of FIG. 1A. For example, instead of the interposer 100 of FIG. 1A, one of the interposers 100a to 100f with reference to FIGS. 2A, 3A, 3B, and 4A to 4C, respectively, may be included in the semiconductor package 1000a. Aspects about the package substrate 1200 and the external sealing member 1600 may be the same as described with respect to the package substrate 1200 and the external sealing member 1600 of the semiconductor package 1000 of FIG. 5.

The semiconductor devices 1300 and 1400 may include the first semiconductor device 1300 and the second semiconductor device 1400. The first semiconductor device 1300 may be stacked on a right side of the interposer 100 through the third external connection terminal 1350. The first semiconductor device 1300 may have a chip or package structure. In the semiconductor package 1000a according to an implementation, the first semiconductor device 1300 may have a chip structure. For example, the first semiconductor device 1300 may include a logic chip. Other aspects about the first semiconductor device 1300 may be the same as described with respect to the first semiconductor device 1300 of the semiconductor package 1000 of FIG. 5.

The second semiconductor device 1400 may include a memory device. The second semiconductor device 1400 may include a memory package, for example, an HBM package. However, the second semiconductor device 1400 is not limited to the HBM package. For example, the second semiconductor device 1400 may have a single chip structure or may have a general package structure that is different from the HBM package. Aspects about the second semiconductor device 1400 may be the same as described with respect to the second semiconductor device 1400 of the semiconductor package 1000 of FIG. 5. Also, aspects about the second semiconductor device 1400 having the HBM package structure may be the same as described with respect to the second semiconductor devices 1400, 1400a, and 1400b of FIGS. 6A to 6C.

Referring to FIG. 7B, the semiconductor package 1000b according to an implementation may differ from the semiconductor package 1000 of FIG. 5 in that the semiconductor package 1000b may include only the first semiconductor device 1300. In detail, the semiconductor package 1000b according to an implementation may include the interposer 100, the package substrate 1200, the first semiconductor device 1300, and the external sealing member 1600.

The interposer 100 may correspond to, for example, the interposer 100 of FIG. 1A. Thus, the interposer 100 may include the interposer lower plate 100-1 and the interposer upper plate 100-2, and the interposer lower plate 100-1 and the interposer upper plate 100-2 may be coupled to each other through HCB. In the semiconductor package 1000b according to an implementation, the interposer 100 is not limited to the interposer 100 of FIG. 1A. For example, instead of the interposer 100 of FIG. 1A, one of the interposers 100a to 100f with reference to FIGS. 2A, 3A, 3B, and 4A to 4C, respectively, may be included in the semiconductor package 1000b. Aspects about the package substrate 1200 and the external sealing member 1600 may be the same as described with respect to the package substrate 1200 and the external sealing member 1600 of the semiconductor package 1000 of FIG. 5.

The first semiconductor device 1300 may be stacked on the interposer 100 through the third external connection terminal 1350. The first semiconductor device 1300 may have a chip or package structure. In the semiconductor package 1000b according to an implementation, the first semiconductor device 1300 may have a chip structure. For example, the first semiconductor device 1300 may include a logic chip. Other aspects about the first semiconductor device 1300 may be the same as described with respect to the first semiconductor device 1300 of the semiconductor package 1000 of FIG. 5.

FIGS. 8A to 8F are cross-sectional views for describing a method of manufacturing an interposer substrate 100S, according to an implementation. FIGS. 8A to 8F are described with reference to FIGS. 1A and 1B, and aspects described above with reference to FIGS. 1A to 7B are briefly described or are not repeatedly described.

Referring to FIG. 8A, according to the method of manufacturing the interposer substrate 100S according to an implementation, first, the first through electrode 120-1 and the first capacitor 140-1 may be formed on an initial first body layer 101-1S to form a first interposer lower plate substrate 100-1Sa. Here, the initial first body layer 101-1S may have the size of a wafer level, and thus, the first interposer lower plate substrate 100-1Sa may have the size of a wafer level and may include a plurality of initial interposer lower plates. Aspects about the first through electrode 120-1 and the first capacitor 140-1 may be the same as described with respect to the first through electrode 120-1 and the first capacitor 140-1 of the interposer lower plate 100-1 of the interposer 100 of FIG. 1A.

Referring to FIG. 8B, after the first through electrode 120-1 and the first capacitor 140-1 are formed, the first interconnect layer 110-1 may be formed on the initial first body layer 101-1S to form a second interposer lower plate substrate 100-1Sb. The first interconnect layer 110-1 may be formed to have the size of a wafer level for entirely covering the initial first body layer 101-1S. The first interconnect layer 110-1 may include the interlayer insulating layer 112, the interconnect lines 114, the via 116, and the Al pad 118. In FIG. 8B, for convenience, only the interlayer insulating layer 112 and the interconnect lines 114 are illustrated. Aspects about the first interconnect layer 110-1 may be the same as described with respect to the first interconnect layer 110-1 of the interposer lower plate 100-1 of the interposer 100 of FIG. 1A.

Referring to FIG. 8C, after the first interconnect layer 110-1 is formed, the first pad 130-1, for example, the first front-side pad 130f-1, may be formed on the first interconnect layer 110-1. Thereafter, the first external connection terminal 150 may be formed on the first front-side pad 130f-1. Aspects about the first front-side pad 130f-1 and the first external connection terminal 150 may be the same as described with respect to the first front-side pad 130f-1 and the first external connection terminal 150 of the interposer lower plate 100-1 of the interposer 100 of FIG. 1A. Through the formation of the first front-side pad 130f-1 and the first external connection terminal 150, a third interposer lower plate substrate 100-1Sc may be formed.

Referring to FIG. 8D, after the first external connection terminal 150 is formed, the third interposer lower plate substrate 100-1Sc may be flipped and fixed to a first carrier substrate 2000 by using an adhesive layer 2500. Thereafter, through grinding and etching, a portion of a back side of the initial first body layer 101-1S may be removed and the first through electrode 120-1 may be exposed. Next, the first back-side protective layer 135b-1 and the first back-side pad 130b-1 may be formed on the back side of the initial first body layer 101-1S. Aspects about the first back-side protective layer 135b-1 and the first back-side pad 130b-1 may be the same as described with respect to the first back-side protective layer 135b-1 and the first back-side pad 130b-1 of the interposer lower plate 100-1 of the interposer 100 of FIG. 1A. By forming the first back-side protective layer 135b-1 and the first back-side pad 130b-1, an interposer lower plate substrate 100-1S may be formed. The interposer lower plate substrate 100-1S may have the size of a wafer level and may include a plurality of interposer lower plates 100-1.

Referring to FIG. 8E, an interposer upper plate substrate 100-2S may be formed through the processes of FIGS. 8A to 8D. However, when the interposer upper plate substrate 100-2S is formed, only the second front-side pad 130f-2 may be formed in the process corresponding to FIG. 8C. That is, the first external connection terminal 150 may not be formed on the interposer upper plate substrate 100-2S. The interposer upper plate substrate 100-2S may also have the size of a wafer level and may include a plurality of interposer upper plates 100-2. The process of forming the interposer lower plate substrate 100-1S and the process of forming the interposer upper plate substrate 100-2S may be separately performed in parallel with each other.

Referring to FIG. 8F, next, the interposer upper plate substrate 100-2S may be coupled to the interposer lower plate substrate 100-1S through HCB. As illustrated, a back side of the interposer upper plate substrate 100-2S may be coupled to a back side of the interposer lower plate substrate 100-1S through HCB. Through the coupling of the interposer lower plate substrate 100-1S and the interposer upper plate substrate 100-2S, the interposer substrate 100S may be manufactured. The interposer substrate 100S may have the size of a wafer level and may include the plurality of interposers 100 of FIG. 1A. Subsequently, the interposer substrate 100S may be separated through dicing along with the structures mounted thereabove, so as to be manufactured as the interposer 100 of FIG. 1A.

For reference, to describe the HCB in more detail, the interposer lower plate substrate 100-1S and the interposer upper plate substrate 100-2S may undergo a plasma process and an ultra-pure cleaning process before a bonding process, and thus, OH dangling bonds may be formed on the first back-side protective layer 135b-1 and the second back-side protective layer 135b-2. Thereafter, the interposer upper plate substrate 100-2S may be bonded to the interposer lower plate substrate 100-1S at room temperature, so that the first back-side pad 130b-1 and the second back-side pad 130b-2 may be aligned with each other. At an early stage of bonding, the OH dangling bonds of the first back-side protective layer 135b-1 of the interposer lower plate substrate 100-1S and the second back-side protective layer 135b-2 of the interposer upper plate substrate 100-2S may form hydrogen bonding. The hydrogen bonding may have a relatively low adhesive force.

Thereafter, heat is applied through annealing, and thus, a solid coupling structure may be formed between the first back-side pad 130b-1 and the second back-side pad 130b-2. In detail, through annealing, a metal expansion process and a metal diffusion process may occur in the first back-side pad 130b-1 and the second back-side pad 130b-2, and through this metal expansion and metal diffusion processes, the first back-side pad 130b-1 and the second back-side pad 130b-2 may be integrally formed. Through annealing, the hydrogen bonding between the first back-side protective layer 135b-1 and the second back-side protective layer 135b-2 may be changed to oxide bonding. For example, to briefly represent this by using a chemical formula, —OH+—OH→O+H₂O through high temperature annealing. The oxide bonding may have a greater adhesive force than the hydrogen bonding. As a result, the interposer lower plate substrate 100-1S and the interposer upper plate substrate 100-2S may be solidly coupled to each other through HCB with high adhesive power.

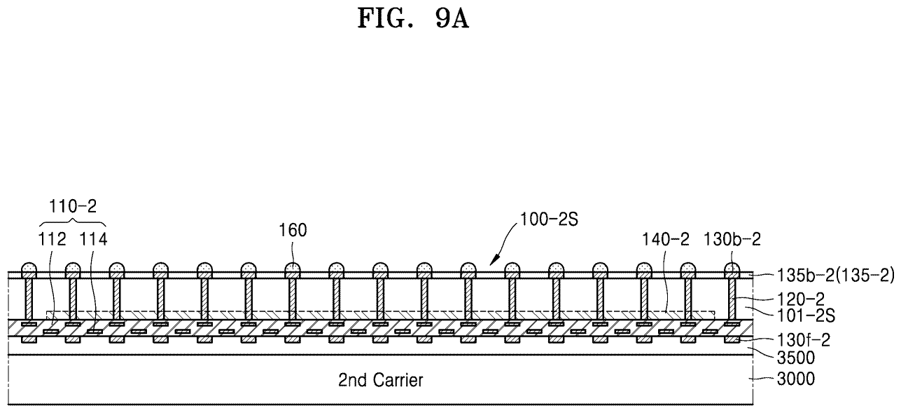

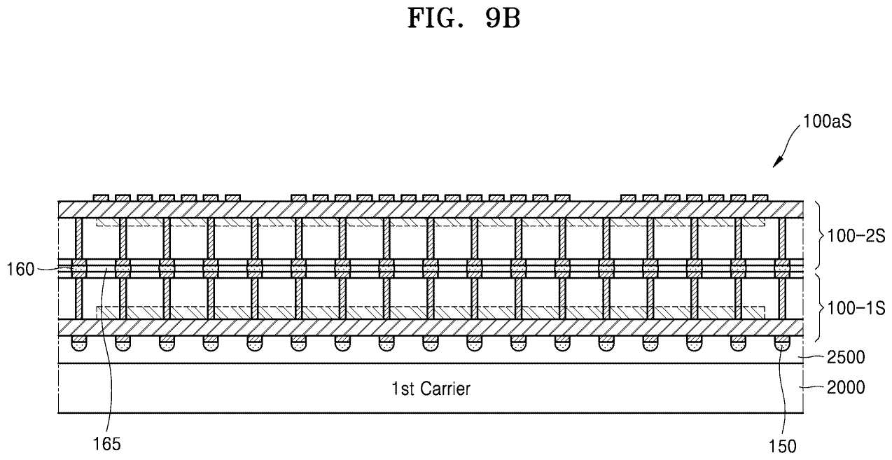

FIGS. 9A and 9B are cross-sectional views for describing a method of manufacturing an interposer substrate 100aS, according to an implementation. FIGS. 9A and 9B are described with reference to FIGS. 2A and 2B, and aspects described above with reference to FIGS. 8A to 8F are briefly described or are not repeatedly described.

Referring to FIG. 9A, according to the method of manufacturing the interposer substrate 100aS according to an implementation, after the interposer upper plate substrate 100-2S is formed in FIG. 8E, the inter-plate connection terminal 160 may be formed on the second back-side pad 130b-2.

Referring to FIG. 9B, next, the interposer upper plate substrate 100-2S may be coupled to the interposer lower plate substrate 100-1S through the inter-plate connection terminal 160. A TCB method may be used for the coupling through the inter-plate connection terminal 160. Also, the adhesive layer 165 may be filled between the interposer lower plate substrate 100-1S and the interposer upper plate substrate 100-2S. The adhesive layer 165 may include, for example, an NCF. However, the adhesive layer 165 is not limited to the NCF. Through the coupling of the interposer lower plate substrate 100-1S and the interposer upper plate substrate 100-2S, the interposer substrate 100aS may be manufactured. The interposer substrate 100aS may have the size of a wafer level and may include the plurality of interposers 100a of FIG. 2A. The interposer substrate 100aS may subsequently be separated through dicing along with the structures mounted thereabove, so as to be manufactured as the interposer 100a of FIG. 2A.

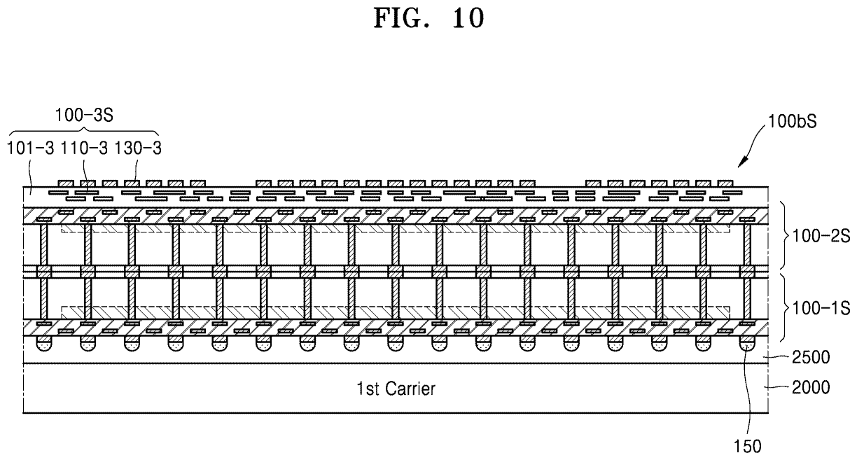

FIG. 10 is a cross-sectional view for describing a method of manufacturing an interposer substrate 100bS, according to an implementation. FIG. 10 is described with reference to FIG. 3A, and aspects described above with reference to FIGS. 8A to 8F are briefly described or are not repeatedly described.

Referring to FIG. 10, according to the method of manufacturing the interposer substrate 100bS according to an implementation, after the interposer substrate 100S is formed in FIG. 8F, a first redistribution layer substrate 100-3S may be formed on the second interconnect layer 110-2 of the interposer upper plate substrate 100-2S. The first redistribution layer substrate 100-3S may be formed to have the size of a wafer level for entirely covering the second interconnect layer 110-2. The first redistribution layer substrate 100-3S may include the first redistribution body layer 101-3, the first redistribution line 110-3, and the first redistribution pad 130-3. Aspects about the first redistribution body layer 101-3, the first redistribution line 110-3, and the first redistribution pad 130-3 may be the same as described with respect to the first redistribution body layer 101-3, the first redistribution line 110-3, and the first redistribution pad 130-3 of the first redistribution layer 100-3 of the interposer 100b of FIG. 3A.

By forming the first redistribution layer substrate 100-3S, the interposer substrate 100bS may be manufactured. The interposer substrate 100bS may have the size of a wafer level and may include the plurality of interposers 100b of FIG. 3A. Subsequently, the interposer substrate 100bS may be separated through dicing along with the structures mounted thereabove, so as to be manufactured as the interposer 100b of FIG. 3A.

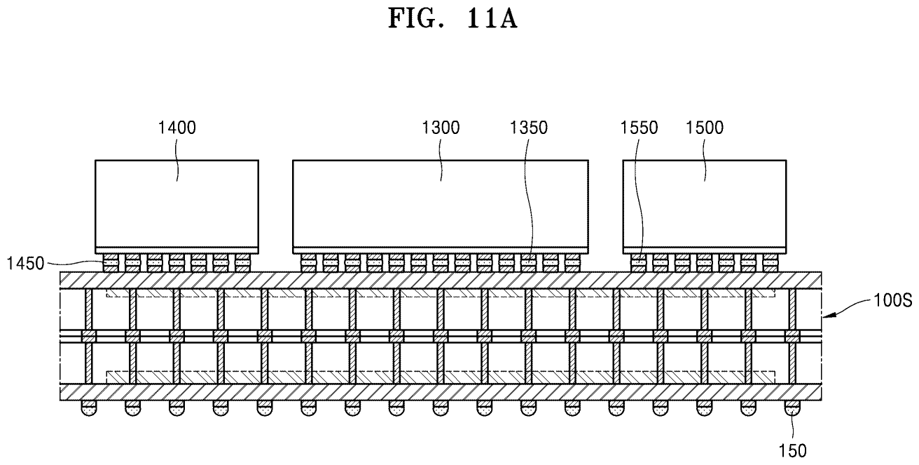

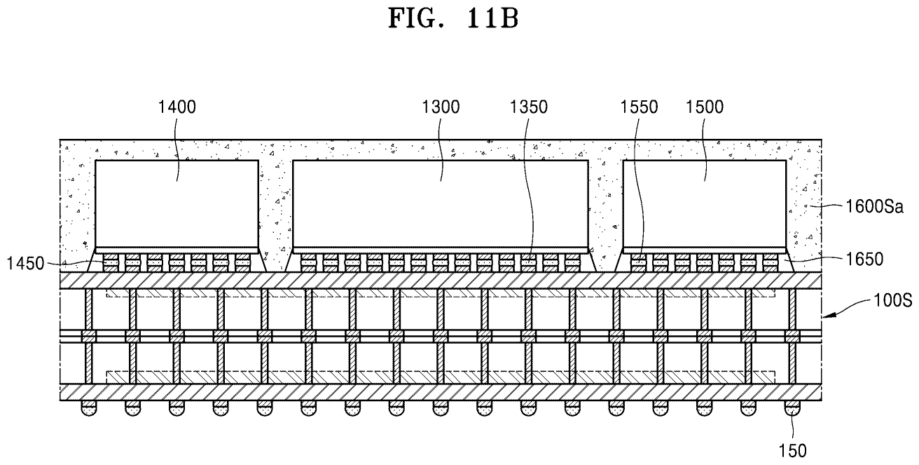

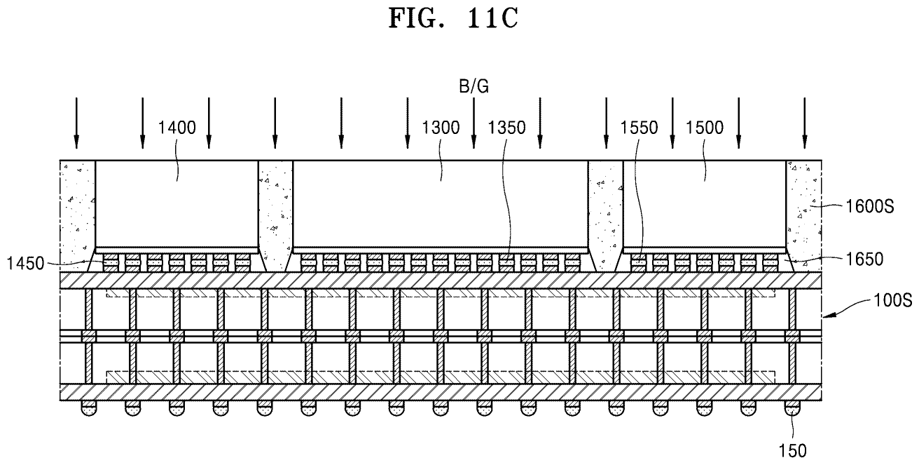

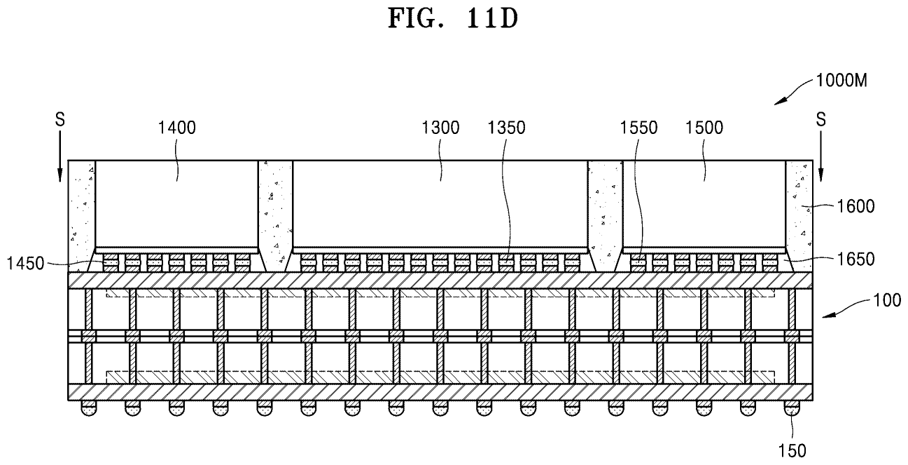

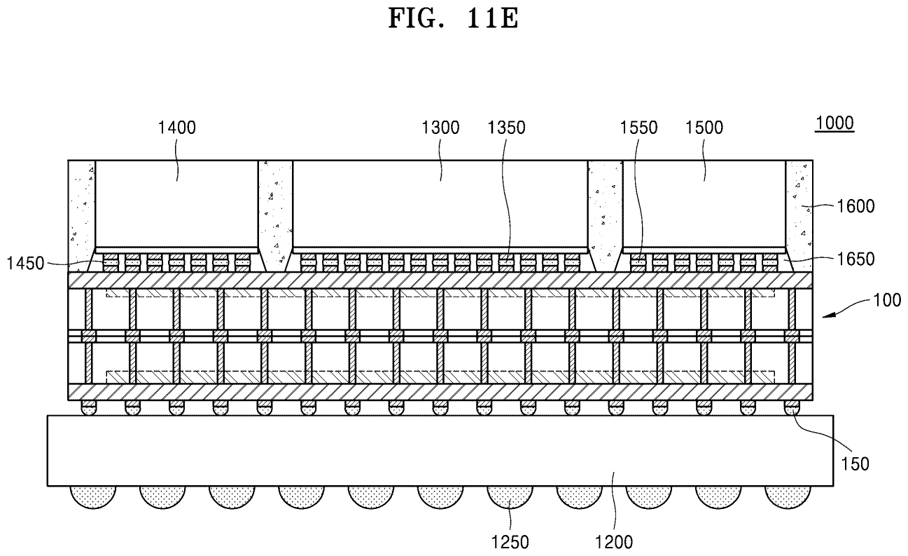

FIGS. 11A to 11E are schematic cross-sectional views for describing a method of manufacturing the semiconductor package 1000, according to an implementation. FIGS. 11A to 11E are described with reference to FIG. 5, and aspects described above with reference to FIGS. 1A to 10 are briefly described or are not repeatedly described.

Referring to FIG. 11A, according to the method of manufacturing the semiconductor package 1000 according to an implementation, first, the semiconductor devices 1300, 1400, and 1500 may be mounted on the interposer substrate 100S. The semiconductor devices 1300, 1400, and 1500 may include, for example, the first semiconductor devices 1300, the second semiconductor devices 1400, and the third semiconductor devices 1500, and may be mounted on the interposer substrate 100S through the external connection terminals 1350, 1450, and 1550. The interposer substrate 100S may have the size of a wafer level and may include the plurality of interposers 100 of FIG. 1A. Aspects about the semiconductor devices 1300, 1400, and 1500 may be the same as described with respect to the semiconductor devices 1300, 1400, and 1500 of the semiconductor package 1000 of FIG. 5.

Referring to FIG. 11B, after the semiconductor devices 1300, 1400, and 1500 are mounted, an external sealing member 1600Sa sealing the semiconductor devices 1300, 1400, and 1500 on the interposer substrate 100S may be formed. The external sealing member 1600Sa may cover side surfaces and upper surfaces of the semiconductor devices 1300, 1400, and 1500. The material, etc. of the external sealing member 1600Sa may be the same as described with respect to the external sealing member 1600 of the semiconductor package 1000 of FIG. 5. The external sealing member 1600Sa can also be referred to as a sealant in the present disclosure.

Referring to FIG. 11C, after forming the external sealing member 1600Sa, an upper portion of the external sealing member 1600Sa may be removed through back grinding B/G. By removing the upper portion of the external sealing member 1600Sa, the upper surfaces of the semiconductor devices 1300, 1400, and 1500 may be exposed through the external sealing member 1600S.

Referring to FIG. 11D, after the back grinding B/G, the interposer substrate 100S and the structures thereabove (also referred to as a stacked structure in the present disclosure) may be separated through sawing S into a plurality of intermediate semiconductor packages. In other words, the stack structure (that is in a wafer configuration) can be diced into a plurality of individual dies. Each die can be an intermediate semiconductor package 1000M. Each intermediate semiconductor package 1000M can include an interposer 100 and the corresponding semiconductor devices 1300, 1400, and 1500 that are stacked on the respective interposer 100.

Referring to FIG. 11E, after manufacturing the intermediate semiconductor package 1000M, the intermediate semiconductor package 1000M may be mounted on the package substrate 1200 through the first external connection terminal 150, and thus, the semiconductor package 1000 may be completely manufactured. The semiconductor package 1000 may correspond to the semiconductor package 1000 of FIG. 5.

Accordingly, the true technical scope of protection of the present disclosure shall be defined by the present disclosure of the appended claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An interposer comprising:
an interposer lower plate; and
an interposer upper plate above the interposer lower plate and coupled to the interposer lower plate,
wherein the interposer lower plate comprises a first body layer, a first capacitor below the first body layer, a first interconnect layer below the first capacitor, and a first pad on an upper surface of the first body layer,
wherein the interposer upper plate comprises a second body layer, a second capacitor above the second body layer, a second interconnect layer above the second capacitor, and a second pad on a lower surface of the second body layer, and
wherein the interposer lower plate is coupled to the interposer upper plate with the first pad being electrically connected to the second pad.

2. The interposer of claim 1, wherein the interposer lower plate and the interposer upper plate are coupled to each other through hybrid copper bonding (HCB).

3. The interposer of claim 1, wherein the interposer lower plate and the interposer upper plate are coupled to each other through a connection terminal.

4. The interposer of claim 1, wherein the interposer lower plate comprises a first through electrode extending through the first body layer, the first through electrode connecting the first interconnect layer with the first pad, and
wherein the interposer upper plate comprises a second through electrode extending through the second body layer, the second through electrode connecting the second interconnect layer with the second pad.

5. The interposer of claim 1, wherein a lower surface of the first interconnect layer is at a front side of the interposer lower plate, and the upper surface of the first body layer is at a back side of the interposer lower plate,
wherein an upper surface of the second interconnect layer is at a front side of the interposer upper plate, and the lower surface of the second body layer is at a back side of the interposer upper plate, and
wherein each of the first capacitor and the second capacitor comprises an integrated stack capacitor (ISC),
wherein the first capacitor is adjacent to the front side of the interposer lower plate, and the second capacitor is adjacent to the front side of the interposer upper plate.

6. The interposer of claim 1, wherein a capacitance of the second capacitor is smaller than or equal to a capacitance of the first capacitor.

7. The interposer of claim 1, comprising one or more redistribution layers below the first interconnect layer and/or above the second interconnect layer.

8. An interposer comprising:
an interposer lower plate; and
an interposer upper plate above the interposer lower plate and coupled to the interposer lower plate,
wherein the interposer lower plate comprises a first body layer, a first capacitor on the first body layer, a first interconnect layer on the first capacitor, a first pad on the first body layer or on the first interconnect layer, and a first through electrode extending through the first body layer,
wherein the interposer upper plate comprises a second body layer, a second capacitor on the second body layer, a second interconnect layer on the second capacitor, a second pad on the second body layer or on the second interconnect layer, and a second through electrode extending through the second body layer, and
wherein the interposer lower plate is coupled to the interposer upper plate with the first pad being electrically connected to the second pad.

9. The interposer of claim 8, wherein the interposer lower plate and the interposer upper plate are coupled to each other through hybrid copper bonding (HCB) or a connection terminal.

10. The interposer of claim 8, wherein the first interconnect layer is at a front side of the interposer lower plate, and the first body layer is at a back side of the interposer lower plate, and wherein the second interconnect layer is at a front side of the interposer upper plate and the second body layer is at a back side of the interposer upper plate, and
wherein the interposer lower plate and the interposer upper plate form a coupling structure, the coupling structure comprising one of:
a first coupling structure with the back side of the interposer lower plate being coupled to the back side of the interposer upper plate;
a second coupling structure with the back side of the interposer lower plate being coupled to the front side of the interposer upper plate;
a third coupling structure with the front side of the interposer lower plate being coupled to the back side of the interposer upper plate; or
a fourth coupling structure with the front side of the interposer lower plate being coupled to the front side of the interposer upper plate.

11. The interposer of claim 10, wherein the interposer lower plate and the interposer upper plate comprise the first coupling structure,
each of the first capacitor and the second capacitor comprises an integrated stack capacitor (ISC), and
a capacitance of the second capacitor is smaller than or equal to a capacitance of the first capacitor.

12. The interposer of claim 10, wherein the interposer lower plate and the interposer upper plate comprise the first coupling structure,
the first capacitor is adjacent to the front side of the interposer lower plate, and
the second capacitor is adjacent to the front side of the interposer upper plate.

13. The interposer of claim 8, comprising one or more redistribution layers on the first interconnect layer and/or the second interconnect layer.

14. A semiconductor package comprising:
a package substrate;
an interposer mounted on the package substrate, the interposer comprising an interposer lower plate and an interposer upper plate coupled to the interposer lower plate; and
at least one semiconductor device mounted on the interposer,
wherein the interposer lower plate comprises a first body layer, a first capacitor below the first body layer, a first interconnect layer below the first capacitor, and a first pad on an upper surface of the first body layer,
wherein the interposer upper plate comprises a second body layer, a second capacitor above the second body layer, a second interconnect layer above the second capacitor, and a second pad on a lower surface of the second body layer, and
wherein the interposer lower plate is coupled to the interposer upper plate with the first pad being electrically connected to the second pad.

15. The semiconductor package of claim 14, wherein the interposer lower plate and the interposer upper plate are coupled to each other through hybrid copper bonding (HCB) or a connection terminal.

16. The semiconductor package of claim 14, wherein each of the first capacitor and the second capacitor comprises an integrated stack capacitor (ISC), and
a capacitance of the second capacitor is smaller than or equal to a capacitance of the first capacitor.

17. The semiconductor package of claim 14, wherein the interposer lower plate comprises a first through electrode extending through the first body layer, the first through electrode connecting the first interconnect layer with the first pad, and
wherein the interposer upper plate comprises a second through electrode extending through the second body layer, the second through electrode connecting the second interconnect layer with the second pad.

18. The semiconductor package of claim 14, wherein a lower surface of the first interconnect layer is at a front side of the interposer lower plate, and an upper surface of the first body layer is at a back side of the interposer lower plate, and
wherein an upper surface of the second interconnect layer is at a front side of the interposer upper plate, and a lower surface of the second body layer is at a back side of the interposer upper plate,
wherein the first capacitor is adjacent to the front side of the interposer lower plate, and
wherein the second capacitor is adjacent to the front side of the interposer upper plate.

19. The semiconductor package of claim 14, comprising one or more redistribution layers being below the first interconnect layer and/or above the second interconnect layer.

20. The semiconductor package of claim 14, wherein the at least one semiconductor device comprises:
a first semiconductor device comprising a logic chip; and
at least one second semiconductor device being adjacent to the first semiconductor device,
wherein the at least one second semiconductor device comprises a memory chip or a memory package.
